(19) United States
(12) Patent Application Publication
(10) Pub. No.: US 2025/0192915 A1
(43) Pub. Date: Jun. 12, 2025

(54) COMMUNICATION SYSTEM AND METHOD FOR ERROR-PROPORTIONAL ENERGY SAVING IN ENCODING AND DECODING IN BODY AREA NETWORKS USING HUMAN BODY COMMUNICATION

(71) Applicant: Quasistatics Inc., West Lafayette, IN (US)

(72) Inventors: Sayantan Dey, Kolkata (IN); Shovan Maity, West Lafayette, IN (US); Shreyas Sen, West Lafayette, IN (US); Sumon Kumar Bose, Krishnagar (IN)

(21) Appl. No.: 18/973,246

(22) Filed: Dec. 9, 2024

Related U.S. Application Data
(60) Provisional application No. 63/608,266, filed on Dec. 10, 2023.

(51) Int. Cl. H04L 1/00; H04B 13/00; H04L 1/20

(52) U.S. Cl. CPC H04L 1/0011; H04B 13/005; H04L 1/203

(57) ABSTRACT

The present invention relates to communication system and method for error-proportional energy-saving in encoding and decoding in Body Area Networks (BAN) using Human Body Communication (HBC). The method includes receiving message signal from data sources. Further, the method includes encoding data symbols using encoding algorithms. Furthermore, the method includes calculating syndrome values for the encoded data symbols. Furthermore, the method includes generating an error signal when the calculated syndrome values corresponds to a non-zero value. Furthermore, the method includes receiving the error signal from the syndrome module. Furthermore, the method includes activating an Error Location Polynomial (ELP) module when the syndrome values corresponds to a non-zero value. Subsequently, the method includes generating an error indication signal. Consequently, the method includes activating an Error Magnitude Polynomial (EMP) solver module and a chien search module. Finally, the method includes decoding the encoded data symbols.

### TECHNICAL FIELD

Embodiments of the present disclosure generally relate to Human Body Communication (HBC) technologies, and more particularly relates to a communication system for error-proportional energy-saving in encoding and decoding in Body Area Networks (BAN) using Human Body Communication (HBC).

### BACKGROUND

Currently, wireless communication has traditionally relied on radio waves due to their advantageous properties, such as the ability to cover large distances and enable non-line-of-sight signaling. Further, radio wave-based wireless communication is instrumental in various applications, including Global Positioning System (GPS), voice, and video transmission. However, these radio-wave based communication links leads to various challenges, so substantial that if not addressed appropriately, could render the communication link unusable.

One of the biggest challenges faced by almost all radio-wave based wireless communication systems is the presence of unwanted interferers within the utilized communication bands, where these interferers could be jamming signals, which may actively try to hinder the communication work's ability to service the users. Further, the interferers may be produced due to use of unlicensed or illegal radio-wave based devices. Furthermore, the interferers could also be part of another communication system whose frequency band coincides, in part or in full, with another system, thereby causing unintentional interference. In many applications radio-wave based communication systems need to operate in covert or discreet mode, ensuring that the presence of their communication signals is either undetectable by other un-intended devices, or if detected, is rendered unintelligible for un-intended devices.

The requirements of low-power, wireless communication around the body as an alternative to traditional wireless communication such as Wireless Fidelity (Wi-Fi), and Bluetooth, have led to the invention of the Human Body Communication (HBC) network exploiting the conductive property of the human body. The application of the HBC may be found in smartwatches for receiving physiological information from different sensor nodes around the body. Further the application of the HBC may also be found in audio transfer from smartphones to head-mounted devices such as headsets, and earbuds, video transfer from head-mounted devices such as smart helmets and smart glasses to smartphones. However, due to antenna property of the human body, the human body picks up electromagnetic interference signals from its surroundings. This leads to loss of information and high energy dissipation in the noise and interference-dominated environment.

Currently in the existing technologies, error correction schemes such as Reed Solomon (RS) coding, Viterbi coding, Turbo-coding, and the like, are deployed in communication networks to correct errors due to the additive channel noise and interferences in the received signals. In other words, Reed Solomon (RS) forward-error correction scheme is well-suited for low-power implementation due to its low-complexity algorithmic implementation which is a perfect match for a battery-operated or charging-free or even in future battery-free devices in low-power human body communication network.

There are several prior attempts of Reed Solomon forward error correction implementation towards power savings like in one of the existing systems which discusses low-power implementation of Chien-search module, one of the modules of Reed Solomon decoding system. The proposal relates to the deployment of Chien search circuitry having at least two hardware components which produce the bits of Chien search output. The method first activates one of the hardware components and checks its output and actives the other hardware components if a certain criterion on the first activated hardware's output is met.

Further, one of the existing system relates to the calculation of syndrome by applying vector operations using a different basis of the vector space. Once all the syndromes are calculated, they are transformed into a common basis of a vector space. The above-mentioned framework consumes less power. Moreover, it discusses calculating the roots of Error Location Polynomials (ELP) using serial multipliers instead of parallel ones on a given field element. The serial multiplier produces sequences of multiplication and interim results. If the interim result indicates the given field is not an ELP's root, the controller stops further calculations and moves on to the next field elements resulting in a power saving in finding the error locations.

Furthermore, in yet another existing system discusses the method of receiving data packets and parity packets in a super-frame and decode the parity packets if the received data packet is incorrect and omitting the decoding if all the packets are correct. The data packet may include a cyclic redundancy check segment which validates the correctness of the received data.

Subsequently, in still another existing system discusses a framework of power saving in chien search implementation utilizing the rank of the Error Location Polynomial (ELP) which is equal to the errors in the received data. The number of functional modules/taps to calculate the roots of the error location polynomial is equal to the maximum error correction capability of the Reed Solomon architecture. The framework actives the number of functional modules which is equation to the rank of the ELP and deactivates rest of the functional modules to save power.

However, all the above-mentioned patents have claimed power saving for the application of flash memory and wireless communication, without any application in Human Body Communication (HBC). Hence there is a need for lowering the power consumption of the reed Solomon encoder and decoder modules specific to working in conjunction with Human Body Communication (HBC) protocols. In other words, since RS error correction scheme is capable of correcting burst errors, the deployment of the Reed Solomon (RS) error correction module in human body communication in the presence of interference is the most efficient in lowering the bit error rate (BER) at the HBC receiver.

Therefore, a need exists for a novel solution that overcomes the limitations of both traditional wireless technologies and error correction schemes. Therefore, there is a need in the art to provide a communication system for error-proportional energy-saving in encoding and decoding in Body Area Networks (BAN) using Human Body Communication (HBC), to address the aforementioned deficiencies in the art.

### SUMMARY

This summary is provided to introduce a selection of concepts, in a simple manner, which is further described in the detailed description of the disclosure. This summary is neither intended to identify key or essential inventive concepts of the subject matter nor to determine the scope of the disclosure.

An aspect of the present disclosure provides a communication system for error-proportional energy savings in encoding and decoding in Body Area Networks (BAN) using Human Body Communication (HBC). The communication system comprises a transmitter further comprising an encoder module configured to receive a message signal from one or more data sources. In an embodiment, the message symbol may comprise one or more data symbols. The encoder module may further be configured to encode the one or more data symbols using one or more encoding algorithms. Further, the communication system comprises a receiver further comprising a decoder module configured to receive the one or more encoded data symbols from the encoder module. The decoder module further comprises at least one syndrome module configured to calculate one or more syndrome values for the received one or more encoded data symbols. In an embodiment, the number of one or more syndrome values may be proportional to twice maximum error correction capacity value of the one or more encoded data symbols. Further, the syndrome module may be configured to generate an error signal when the calculated one or more syndrome values corresponds to a non-zero value. Furthermore, the decoder module comprises at least one clock gate controller configured to receive the error signal from the at least one syndrome module, and activate an Error Location Polynomial (ELP) module when the one or more syndrome values corresponds to a non-zero value. Further, the at least one clock gate controller may be configured to generate an error indication signal, based on the activated ELP module. In an embodiment, the error indication signal may correspond to number of errors present in the one or more encoded data symbols. Furthermore, the at least one clock gate controller may be configured to activate an Error Magnitude Polynomial (EMP) solver module and a chien search module based on determining polarity of the error indication signal, and may decode the one or more encoded data symbols based on the activated EMP solver module and the chien search module. Subsequently, the communication system comprises a communication medium configured to establish communication sessions between the transmitter and the receiver. Further, the communication medium may be configured to route the data between the transmitter and the receiver using the established communication sessions.

Another aspect of the present disclosure includes a communication method for error-proportional energy saving in encoding and decoding in Body Area Networks (BAN) using Human Body Communication (HBC). The method includes receiving, by an encoder module, a message signal from one or more data sources. In an embodiment, the message symbol may comprise one or more data symbols. Further, the method includes encoding, by the encoder module, the one or more data symbols using one or more encoding algorithms. Furthermore, the method includes calculating, by at least one syndrome module, one or more syndrome values for the received one or more encoded data symbols. In an embodiment, the number of one or more syndrome values may be proportional to twice maximum error correction capacity value of the one or more encoded data symbols. Furthermore, the method includes generating, by the at least one syndrome module, an error signal when the calculated one or more syndrome values corresponds to a non-zero value. Furthermore, the method includes receiving, by at least one clock gate controller, the error signal from the at least one syndrome module. Furthermore, the method includes activating, by the at least one clock gate controller, an Error Location Polynomial (ELP) module when one or more syndrome values corresponds to a non-zero value. Subsequently, the method includes generating, by the at least one clock gate controller, an error indication signal, based on the activated ELP module. In an embodiment, the error indication signal may correspond to number of errors present in the one or more encoded data symbols. Consequently, the method includes activating, by the at least one clock gate controller, an Error Magnitude Polynomial (EMP) solver module and a chien search module based on determining polarity of the error indication signal. Finally, the method includes decoding, by the at least one clock gate controller, the one or more encoded data symbols based on the activated EMP solver module and the chien search module.

Yet another aspect of the present disclosure provides a non-transitory computer-readable medium comprising machine-readable instructions that are executable by a processor to perform the method steps as described above.

To further clarify the advantages and features of the present disclosure, a more particular description of the disclosure will follow by reference to specific embodiments thereof, which are illustrated in the appended figures. It is to be appreciated that these figures depict typical embodiments of the disclosure and are therefore not to be considered limiting in scope. The disclosure will be described and explained with additional specificity and detail with the appended figures.

### BRIEF DESCRIPTION OF ACCOMPANYING DRAWINGS

The disclosure will be described and explained with additional specificity and detail with the accompanying figures in which:

FIG. 1A illustrates an exemplary environment for error-proportional energy saving in encoding and decoding in Body Area Networks (BAN) using Human Body Communication (HBC), in accordance with an embodiment of the present disclosure.

FIG. 1B illustrates an exemplary representation of a human body containing a transmitter and a receiver, in accordance with an embodiment of the present disclosure.

FIG. 2 illustrates a detailed internal block diagram of an encoder module, in accordance with an embodiment of the present disclosure.

FIG. 3A illustrates an internal hardware architecture of a transmitter comprising at least one serializer module, in accordance with an embodiment of the present disclosure.

FIG. 3B illustrates the operation cycle of the at least one serializer module, in accordance with an embodiment of the present disclosure.

FIG. 4 illustrates an internal hardware architecture of a transmitter comprising at least one modulator, in accordance with an embodiment of the present disclosure.

FIG. 5 illustrates a detailed internal block diagram of a decoder module, in accordance with an embodiment of the present disclosure.

FIG. 6A illustrates an internal hardware architecture of a receiver comprising at least one demodulator and at least one de-serializer module, in accordance with an embodiment of the present disclosure.

FIG. 6B illustrates the operation cycle of the at least one de-serializer module, in accordance with an embodiment of the present disclosure.

FIG. 7 illustrates an internal hardware architecture of a decoder module, in accordance with an embodiment of the present disclosure.

FIG. 8 illustrates an exemplary representation of a dataflow in the decoder module, as shown in FIG. 7, in accordance with an embodiment of the present disclosure.

FIG. 9 illustrates an internal hardware architecture of a syndrome module, in accordance with an embodiment of the present disclosure.

FIG. 10 illustrates an internal hardware architecture of a parallel syndrome calculator unit, in accordance with an embodiment of the present disclosure.

FIG. 11 illustrates an internal hardware architecture of an error detection module, in accordance with an embodiment of the present disclosure.

FIG. 12 illustrates an internal hardware architecture of a syndrome out module, in accordance with an embodiment of the present disclosure.

FIG. 13 illustrates an internal block diagram of at least one clock gate controller, in accordance with an embodiment of the present disclosure.

FIG. 14 illustrates a generic block diagram of a clock gate module, in accordance with an embodiment of the present disclosure.

FIG. 15 illustrates an exemplary representation of clock enable signal generation in the syndrome out module, as shown in FIG. 9, in accordance with an embodiment of the present disclosure.

FIG. 16 illustrates an exemplary representation of clock enable signal generation in the Error Location Polynomial (ELP) module, as shown in FIG. 7, in accordance with an embodiment of the present disclosure.

FIG. 17 illustrates an exemplary representation of clock enable signal generation in the chien search module, as shown in FIG. 7, in accordance with an embodiment of the present disclosure.

FIG. 18 illustrates an exemplary graphical representation of an estimated energy per bit of the encoder module with and without clock gating, in accordance with an embodiment of the present disclosure.

FIG. 19 illustrates an exemplary graphical representation of an estimated energy per bit of the syndrome module with and without clock gating, in accordance with an embodiment of the present disclosure.

FIG. 20 illustrates an exemplary graphical representation of an estimated energy per bit of the decoder module for one or more different errors, in accordance with an embodiment of the present disclosure.

FIG. 21 illustrates an exemplary graphical representation of latency of the decoder module for one or more different errors, in accordance with an embodiment of the present disclosure.

FIGS. 22A-22B illustrates a flow chart representation of method for error-proportional energy saving in encoding and decoding in Body Area Networks (BAN) using Human Body Communication (HBC), in accordance with an embodiment of the present disclosure.

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show those specific details that are pertinent to understanding the embodiments of the present disclosure so as not to obscure the figures with details that will be readily apparent to those skilled in the art having the benefit of the description herein.

### DETAILED DESCRIPTION

For simplicity and illustrative purposes, the present disclosure is described by referring mainly to examples thereof. The examples of the present disclosure described herein may be used together in different combinations. In the following description, details are set forth in order to provide an understanding of the present disclosure. It will be readily apparent, however, that the present disclosure may be practiced without limitation to all these details. Also, throughout the present disclosure, the terms “a” and “an” are intended to denote at least one of a particular element. The terms “a” and “an” may also denote more than one of a particular element. As used herein, the term “includes” means includes but not limited to, the term “including” means including but not limited to. The term “based on” means based at least in part on, the term “based upon” means based at least in part upon, and the term “such as” means such as but not limited to. The term “relevant” means closely connected or appropriate to what is being performed or considered.

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated system, and such further applications of the principles of the disclosure as would normally occur to those skilled in the art are to be construed as being within the scope of the present disclosure. It will be understood by those skilled in the art that the foregoing general description and the following detailed description are exemplary and explanatory of the disclosure and are not intended to be restrictive thereof.

In the present document, the word “exemplary” is used herein to mean “serving as an example, instance, or illustration”. Any embodiment or implementation of the present subject matter described herein as “exemplary” is not necessarily to be construed as preferred or advantageous over other embodiments. The terms “comprise”, “comprising”, or any other variations thereof, are intended to cover a non-exclusive inclusion, such that one or more devices or sub-systems or elements or structures or components preceded by “comprises . . . a” does not, without more constraints, preclude the existence of other devices, sub-systems, additional sub-modules. Appearances of the phrase “in an embodiment”, “in another embodiment”, “in an exemplary embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are and not intended to be limiting. A computer system (standalone, client, or server, or computer-implemented system) configured by an application may constitute a “module” (or “subsystem”) that is configured and operated to perform certain operations. In one embodiment, the “module” or “subsystem” may be implemented mechanically or electronically, so a module includes dedicated circuitry or logic that is permanently configured (within a special-purpose processor) to perform certain operations. In another embodiment, a “module” or a “subsystem” may also comprise programmable logic or circuitry (as encompassed within a general-purpose processor or other programmable processor) that is temporarily configured by software to perform certain operations. Accordingly, the term “module” or “subsystem” should be understood to encompass a tangible entity, be that an entity that is physically constructed permanently configured (hardwired), or temporarily configured (programmed) to operate in a certain manner and/or to perform certain operations described herein.

Embodiments described herein provide a communication system and method for error-proportional energy saving in encoding and decoding in Body Area Networks (BAN) using Human Body Communication (HBC). The communication system comprises a transmitter further comprising an encoder module configured to receive a message signal from one or more data sources. In an embodiment, the message symbol may comprise one or more data symbols. The encoder module may further be configured to encode the one or more data symbols using one or more encoding algorithms. Further, the communication system comprises a receiver further comprising a decoder module configured to receive the one or more encoded data symbols from the encoder module. The decoder module further comprises at least one syndrome module configured to calculate one or more syndrome values for the received one or more encoded data symbols. In an embodiment, the number of one or more syndrome values may be proportional to twice maximum error correction capacity value of the one or more encoded data symbols. Further, the syndrome module may be configured to generate an error signal when the calculated one or more syndrome values corresponds to a non-zero value. Furthermore, the decoder module comprises at least one clock gate controller configured to receive the error signal from the at least one syndrome module, and activate an Error Location Polynomial (ELP) module when the calculated one or more syndrome values corresponds to a non-zero value. Further, the at least one clock gate controller may be configured to generate an error indication signal, based on the activated ELP module. In an embodiment, the error indication signal may correspond to number of errors present in the one or more encoded data symbols. Furthermore, the at least one clock gate controller may be configured to activate an Error Magnitude Polynomial (EMP) solver module and a chien search module based on determining polarity of the error indication signal, and may decode the one or more encoded data symbols based on the activated EMP solver module and the chien search module. Subsequently, the communication system comprises a communication medium configured to establish communication sessions between the transmitter and the receiver. Further, the communication medium may be configured to route the data between the transmitter and the receiver using the established communication sessions.

In an embodiment, the present disclosure facilitates the use of an energy-adaptive encoding module and a decoding module for a Human Body Communication (HBC) that opportunistically saves energy when the HBC channel is either very good or very bad, lowering the overall consumed energy on average.

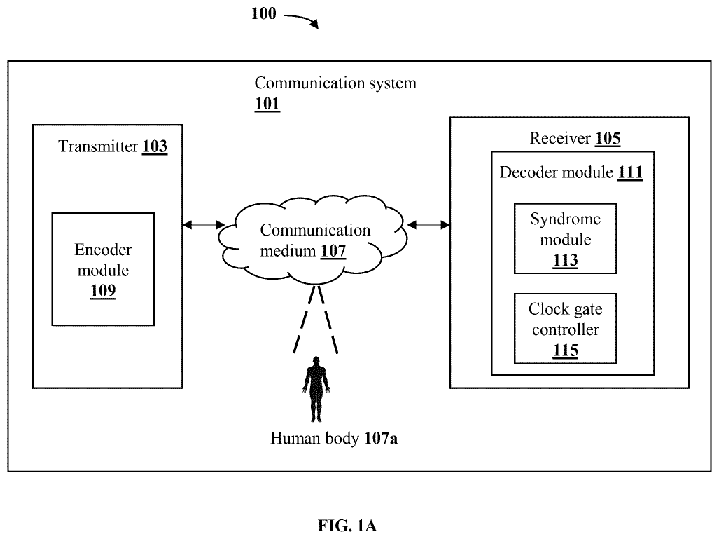

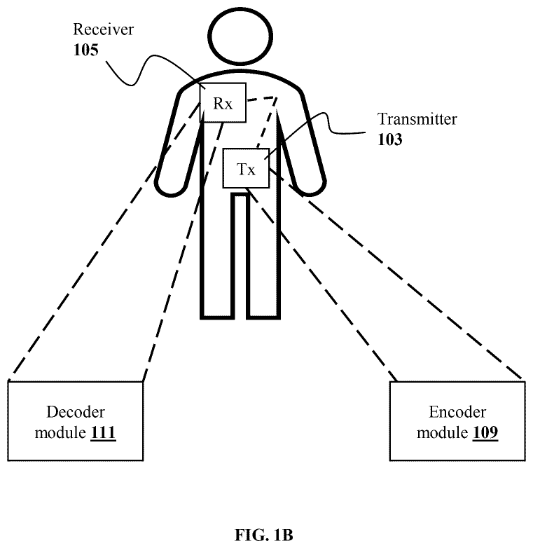

Referring now to the drawings, and more particularly to FIG. 1A through FIG. 22B, where similar reference characters denote corresponding features consistently throughout the figures, there are shown preferred embodiments, and these embodiments are described in the context of the following exemplary system and/or method.

FIG. 1A illustrates an exemplary environment 100 for error-proportional energy saving in encoding and decoding in Body Area Networks (BAN) using Human Body Communication (HBC). As illustrated in FIG. 1A, the exemplary environment 100 may include a communication system 101. Further, the communication system 101 may include a transmitter 103, a receiver 105, and a communication medium 107. In an embodiment, the communication medium 107 may include, but not limited to, a human body 107a (as shown in FIG. 1A).

Further, in an embodiment, the transmitter 103 may comprise an encoder module 109. The encoder module 109 may be configured to receive a message signal from one or more data sources. In an embodiment, the message signal may comprise one or more data symbols. Further, in an embodiment, the message signal may comprise at least one of an audio signal, a video signal, and an image signal. Further, the encoder module 109 may be configured to encode the one or more data symbols using one or more encoding algorithms.

Furthermore, the receiver 105 may comprise a decoder module 111 configured to receive the one or more encoded data symbols from the encoder module 109. In an embodiment, the decoder module 111 further may comprise at least one syndrome module 113 configured to calculate one or more syndrome values for the received one or more encoded data symbols. In an embodiment, the number of one or more syndrome values may be proportional to twice maximum error correction capacity value of the one or more encoded data symbols. Further, the at least one syndrome module 113 may be configured to generate an error signal when the calculated one or more syndrome values corresponds to a non-zero value.

Further, in an embodiment, the decoder module 111 may comprise at least one clock gate controller 115 configured to receive the error signal from the at least one syndrome module 113, and activate an Error Location Polynomial (ELP) module (not shown in FIG. 1A) when the one or more syndrome values corresponds to a non-zero value. Further, the at least one clock gate controller 115 may be configured to generate an error indication signal, based on the activated ELP module. In an embodiment, the error indication signal may correspond to number of errors present in the one or more encoded data symbols.

Furthermore, in an embodiment, the at least one clock gate controller 115 may be configured to activate an Error Magnitude Polynomial (EMP) solver module and a chien search module (not shown in FIG. 1A) based on determining polarity of the error indication signal. Subsequently, the at least one clock gate controller 115 may decode the one or more encoded data symbols based on the activated EMP solver module and the chien search module.

In an embodiment, the communication medium 107 may be configured to establish communication sessions between the transmitter 103 and the receiver 105, and may route the data between the transmitter 103 and the receiver 105 using the established communication sessions.

FIG. 1B illustrates an exemplary representation of a human body 107a containing a transmitter (Tx) 103 and a receiver (Rx) 105, in accordance with an embodiment of the present disclosure.

As shown in FIG. 1B, the human body 107a may include the transmitter (Tx) 103 and the receiver (Rx) 105. In an embodiment, the transmitter 103, and the receiver 105 may be placed in, on, and around the human body 107a. For example, the transmitter 103 or a receiver 105 may be a part of a wearable device such as for example, but not limited to, a smartwatch. Further, a single device such as for example, but not limited to, the smartwatch may act as either the transmitter 103 or the receiver 105 at a point of time, but not simultaneously.

In an embodiment, the transmitter 103 mounted on the human body 107a may include the encoder module 109 such as for example, but not limited to, a RS encoder module. Further, in an embodiment, the receiver 105 mounted on the human body 107a may include the decoder module 111 such as for example, but not limited to, a RS decoder module. The encoder module 109 and the decoder module 111 may support the communication protocol of the human body 107a. In other words, the human body 107a may act as the communication medium 107a for transferring data from the transmitter 103 to the receiver 105.

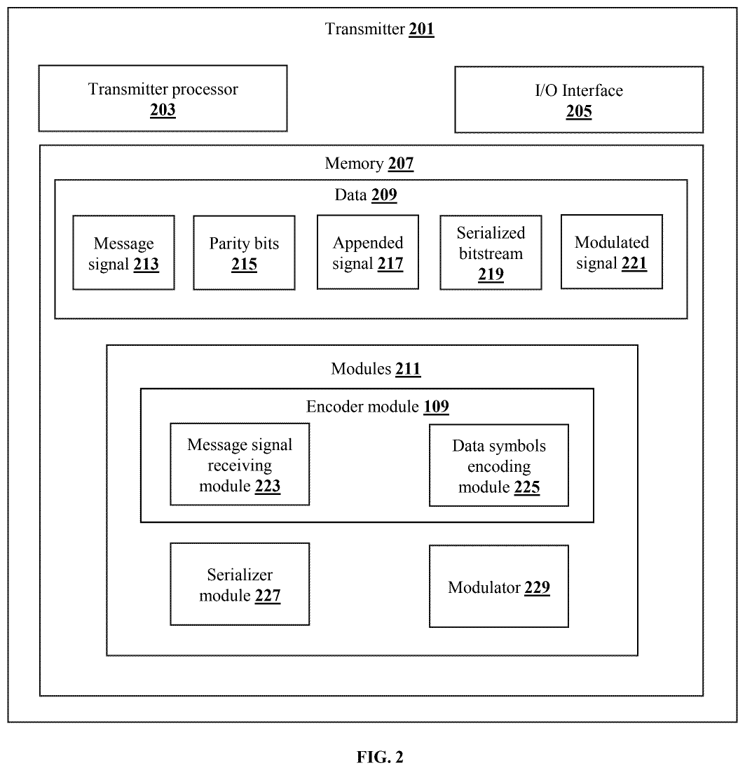

FIG. 2 illustrates a detailed internal block diagram of a transmitter 201, in accordance with an embodiment of the present disclosure. In an embodiment, the transmitter 201 is similar to the transmitter 103 of FIG. 1A.

The transmitter 201 may include, without limiting to, a transmitter processor 203, an I/O interface 205, and a memory 207 storing instructions, executable by the transmitter processor 203, which, on execution, may cause the transmitter 201 to perform error-proportional energy saving in encoding in Body Area Networks (BAN) using Human Body Communication (HBC). In an embodiment, the memory 207 may include data 209 and one or more modules 211. In an embodiment, each of the one or more modules 211 may be a hardware unit which may be outside the memory 207 and coupled with the transmitter 201. In an embodiment, the data 209 may include for example, a message signal 213, a plurality of parity bits 215, an appended signal 217, a serialized bitstream 219, and a modulated signal 221. Further in an embodiment, the one or more modules 211 may include an encoder module 109 comprising a message signal receiving module 223, and a data symbols encoding module 225. Further, the one or more modules 211 may include at least one serializer module 227, and at least one modulator 229.

In an embodiment, the transmitter 201 may be placed in, on, and around the human body 107a (as shown in FIG. 1B).

In an embodiment, the message signal receiving module 223 may be configured to receive the message signal 213 from one or more data sources. Further, in an embodiment, the message signal 213 may comprise one or more data symbols. Furthermore, in an embodiment, the message signal 213 may comprise at least one of an audio signal, a video signal, and an image signal.

In an embodiment, the data symbols encoding module 225 may be configured to encode the one or more data symbols using one or more encoding algorithms. For example, the one or more encoding algorithms may include, for example, but not limited to, a Reed Solomon (RS) encoding algorithm.

In an embodiment, the at least one serializer module 227 may be configured to receive the appended signal 217 from the encoder module 109 associated with the transmitter 201. In an embodiment, the appended signal 217 may comprise the message signal 213 and the plurality of parity bits 215, in which the plurality of parity bits 215 may be generated by the encoder module 109. Further, the at least one serializer module 227 may be configured to convert one or more data symbols present in the appended signal 217 into an input bit stream. Furthermore, the at least one serializer module 227 may determine number of bits present in the appended signal 217 based on the generated input bit stream, and may dynamically activate the encoder module 109 in first set of cycle operations based on the determined number of bits. Furthermore, the at least one serializer module 227 may be configured to dynamically deactivate the encoder module 109 in second set of cycle operations, for generating the serialized bit stream 219, based on the determined number of bits.

In an embodiment, the at least one modulator 229 may be configured to receive the serialized bit stream 219 from the at least one serializer module 227, and may convert the serialized bit stream 219 into the modulated signal 221 by modulating the serialized bit stream 219.

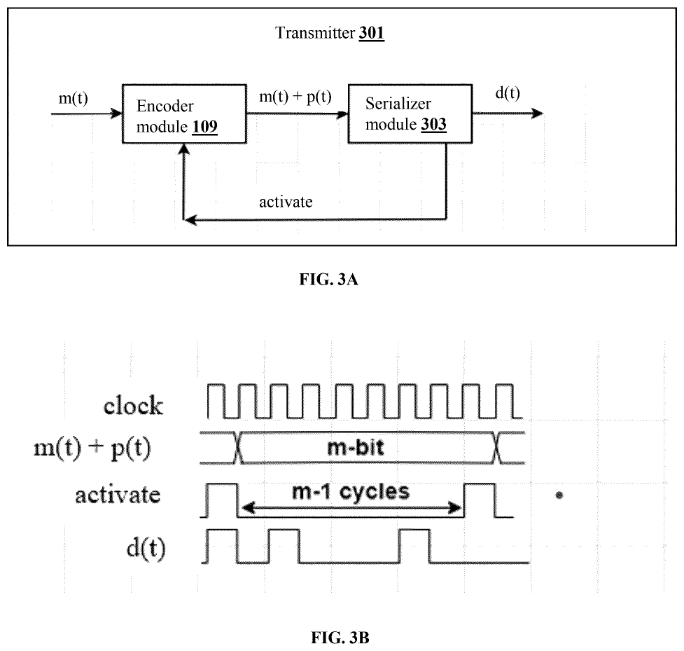

FIG. 3A illustrates an internal hardware architecture of a transmitter 301 comprising at least one serializer module, in accordance with an embodiment of the present disclosure. In an embodiment, the transmitter 301 is similar to the transmitter 103 of FIG. 1, and the transmitter 201 of FIG. 2.

In an embodiment, as shown in FIG. 3A, the transmitter 301 may comprise at least one serializer module 303. In an embodiment, the at least one serializer module 303 is similar to the at least one serializer module 227 of FIG. 2. The serializer module 303 may be configured to receive an appended signal 217 from the encoder module 109 associated with the transmitter 103. In an embodiment, the appended signal 217 may comprise the message signal 213 and the plurality of parity bits 215, in which the plurality of parity bits 215 may be generated by the encoder module 109.

In an embodiment, the encoder module 109 may receive the message signal 213 from the plurality of data sources. In an embodiment, the message signal 213 may be represented as shown in equation (1):

$$Message signal = m ( t ) \qquad ( 1 )$$

For example, the message signal 213 may include, but not limited to, any sort of n-bit binary information from audio, video or image sensors or from a file. Further, in an embodiment, the message signal 213 may comprise one or more data symbols. For example, the message signal 213 may include, but not limited to, k symbols represented as shown in equation (2):

$$m ( t ) = \{ {s}_{1} , {s}_{2} , … , {s}_{k} \} \qquad ( 2 )$$

Further, the encoder module 109 may encode the message signal 213, using the one or more encoding algorithms. In an embodiment, the encoder module 109, may include, for example, but not limited to, a Reed Solomon (RS) encoder.

Further, the encoder module 109 may generate the plurality of parity bits 215 based on the received message signal 213 m(t). In an embodiment, the plurality of parity bits 215 may be represented as shown in equation (3):

$$Party bits = p ( t ) \qquad ( 3 )$$

For example, the encoder module 109 may generate, but not limited to, ‘2t’ parity symbols represented as shown in equation (4):

$$p ( t ) = \{ {p}_{1} , {p}_{2} , … , {p}_{2 t} \} \qquad ( 4 )$$

In an embodiment, the ‘2t’ parity symbols may enable the decoder module 111 to recover the corrupted transmitted data at the receiver 105. Further, in an embodiment, the maximum error correction capability of the decoder module 111 may be, for example, but not limited to ‘t’. That is, each data symbol may consist of n bits data where k+2t<=2ⁿ−1.

Further, in an embodiment, the encoder module 109 may append the message signal 213 and the plurality of parity bits 215 to generate the appended signal 217. In an embodiment, the appended signal 217 may be represented as shown in equation (5):

$$Appended signal = m ( t ) + p ( t ) \qquad ( 5 )$$

FIG. 3B illustrates the operation cycle of the at least one serializer module 303, in accordance with an embodiment of the present disclosure.

In an embodiment, the at least one serializer module 303 may receive the appended signal 217 from the encoder module 109, and may convert one or more data symbols present in the appended signal 217 into an input bit stream. Further, the at least one serializer module 303 may be configured to determine number of bits present in the appended signal 217 based on the generated input bit stream, and may dynamically activate the encoder module 109 in first set of cycle operations based on the determined number of bits.

Furthermore, the at least one serializer module 303 may be configured to dynamically deactivate the encoder module 109 in second set of cycle operations, for generating a serialized bit stream 219, based on the determined number of bits. In an embodiment, the first set of cycle operations may comprise at least a first cycle and the second set of cycle operations may comprise at least remaining cycles excluding the first cycle, in which the sum of the first set of cycle operations and the second set of cycle operations may correspond to total number of bits present in the input bitstream. For example, the first set of cycle operations may include, for example, but not limited to, m cycles, and the second set of cycle operations may include, m−1 cycles.

In an embodiment, for example, the encoder module 109 may process m-bit per clock cycle of the input bitstream. Further, the at least one serializer module 303 may take ‘m’ clock cycles to serialize the m-bit data (as shown in FIG. 3B), and may send an activation signal to the encoder module 109 for a single clock cycle. Further, the encoder module 109 may deactivate the encoder module 109 for rest of the m−1 clock cycles. Once the all the messages encoding is done, the encoder module 109 may completely get deactivated along with the at least one serializer module 303.

Furthermore, in an embodiment, the generated serialized bit stream 219 may be represented as shown in equation (6):

$$Serialized bit stream = d ( t ) \qquad ( 6 )$$

In an embodiment, the at least one serializer module 303 may allow the transmitter 103 to transmit information bits serially.

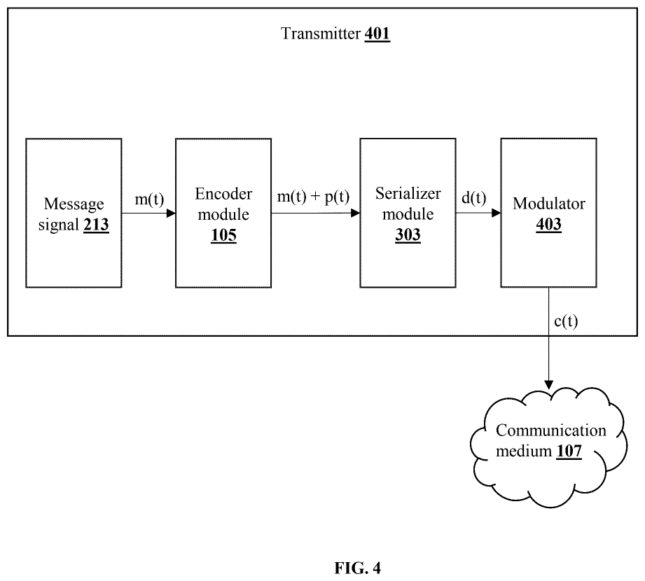

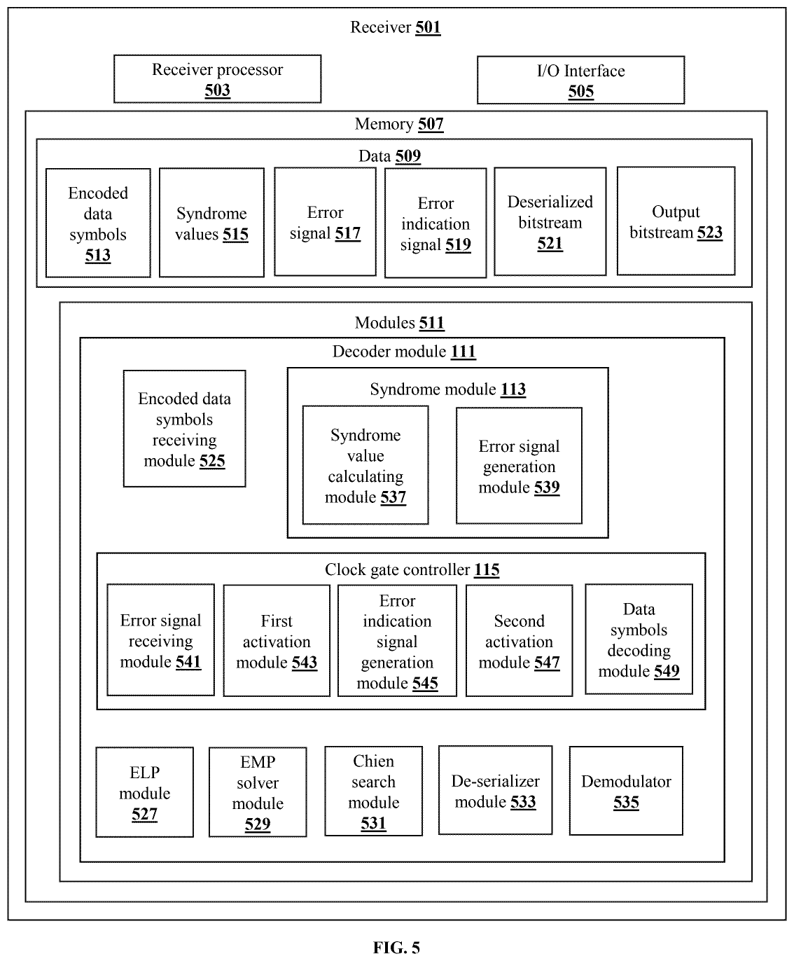

FIG. 4 illustrates an internal hardware architecture of a transmitter 401 comprising at least one modulator 403, in accordance with an embodiment of the present disclosure. In an embodiment, the modulator 403 is similar to the modulator 229 of FIG. 2.

In an embodiment, the transmitter 401 may comprise at least one modulator 403. In an embodiment, the transmitter 401 is similar to the transmitter 103 of FIG. 1A, the transmitter 201 of FIG. 2, and the transmitter 301 of FIG. 3A.

In an embodiment, the at least one modulator 403 may be configured to receive the serialized bit stream 219, represented as d(t), from the at least one serializer module 303.

Furthermore, the at least one modulator 403 may be configured to convert the serialized bit stream 219 into a modulated signal 221 by modulating the serialized bit stream 219. In an embodiment, the modulated signal 221 may be represented as shown in equation (7):

$$Modulated signal = c ( t ) \qquad ( 7 )$$

Further, in an embodiment, the at least one modulator 403 may be configured to couple with the human body 107a (as shown in FIG. 1A) using one or more dry electrodes.

In an embodiment, further, the modulator 403 may pass the modulated signal 221, represented as c(t), into the communication medium 107 (as shown in FIG. 4).

FIG. 5 illustrates a detailed internal block diagram of a receiver 501, in accordance with an embodiment of the present disclosure. In an embodiment, the 501 is similar to the receiver 105 of FIG. 1A.

The receiver 501 may include, without limiting to, a receiver processor 503, an I/O interface 505, and a memory 507 storing instructions, executable by the receiver processor 503, which, on execution, may cause the receiver 501 to perform error-proportional energy-saving in decoding in Body Area Networks (BAN) using Human Body Communication (HBC). In an embodiment, the memory 507 may include data 509 and one or more modules 511. In an embodiment, each of the one or more modules 511 may be a hardware unit which may be outside the memory 507 and coupled with the decoder module 111. In an embodiment, the data 509 may include for example, one or more encoded data symbols 513, one or more syndrome values 515, an error signal 517, an error indication signal 519, a deserialized bitstream 521, and an output bitstream 523. Further in an embodiment, the one or more modules 511 may include a decoder module 111 comprising an encoded data symbols receiving module 525, a syndrome module 113, at least one clock gate controller 115, an Error Location Polynomial (ELP) module 527, an Error Magnitude Polynomial (EMP) solver module 529, a Chien search module 531, at least one de-serializer module 533, and at least one demodulator 535.

Further, the syndrome module 113 may include a syndrome value calculating module 537, and an error signal generation module 539. Furthermore, the at least one clock gate controller 115 may include an error signal receiving module 541, a first activation module (do we need to specify the module?) 543, an error indication signal generation module 545, a second activation module (do we need to specify the module?) 547, and a data symbols decoding module 549. In an embodiment, the decoder module 111 may include, for example, but not limited to, a Reed Solomon (RS) decoder module. In an embodiment, the receiver 501 may be placed in, on, and around the human body 107a (as shown in FIG. 1A).

In an embodiment, the encoded data symbols receiving module 525 may be configured to receive the one or more encoded data symbols 513 from the encoder module 109.

In an embodiment, the syndrome value calculating module 537 may be configured to calculate one or more syndrome values 515 for the received one or more encoded data symbols 513. Further, in an embodiment, the number of one or more syndrome values 515 may be proportional to twice maximum error correction capacity value of the one or more encoded data symbols 513.

In an embodiment, the error signal generation module 539 may be configured to generate an error signal 517 when the calculated one or more syndrome values 515 corresponds to a non-zero value.

In an embodiment, the error signal receiving module 541 may be configured to receive the error signal 517 from the at least one syndrome module 113 (as shown in FIG. 5).

In an embodiment, the first activation module 543 may be configured to activate an Error Location Polynomial (ELP) module 527 when the one or more syndrome values 515 corresponds to a non-zero value.

In an embodiment, the error indication signal generation module 545 may be configured to generate an error indication signal 519, based on the activated ELP module 527. In an embodiment, the error indication signal 519 may correspond to number of errors present in the one or more encoded data symbols 513.

In an embodiment, the second activation module 547 may be configured to activate an Error Magnitude Polynomial (EMP) solver module 529 and a Chien search module 531 based on determining polarity of the error indication signal 519.

In an embodiment, the data symbols decoding module 549 may be configured to decode the one or more encoded data symbols 513 based on the activated EMP solver module 529 and the Chien search module 531.

In an embodiment, the at least one demodulator 535 may be configured to receive the modulated signal 221 from the modulator 229 associated with the transmitter 201, through the communication medium 107. Further, the at least one demodulator 535 may be configured to receive a noise signal and interference signal from surroundings of the BAN. Furthermore, the at least one demodulator 535 may create an output bitstream 523 by demodulating the modulated signal 221, the noise signal and the interference signal (not shown in FIG. 5).

In an embodiment, the at least one de-serializer module 533 may be configured to determine number of bits present in the output bitstream 523, and dynamically activate the decoder module 111 in third set of cycle operations, based on the determined number of bits. Further, the at least one de-serializer module 533 may be configured to dynamically de-deactivate the decoder module 111 in fourth set of cycle operations, for generating a de-serialized bit stream 521, based on the determined number of bits. Finally, the at least one de-serializer module 533 may convert the output bitstream 523 into the one or more data symbols based on the generated de-serialized bit stream 521.

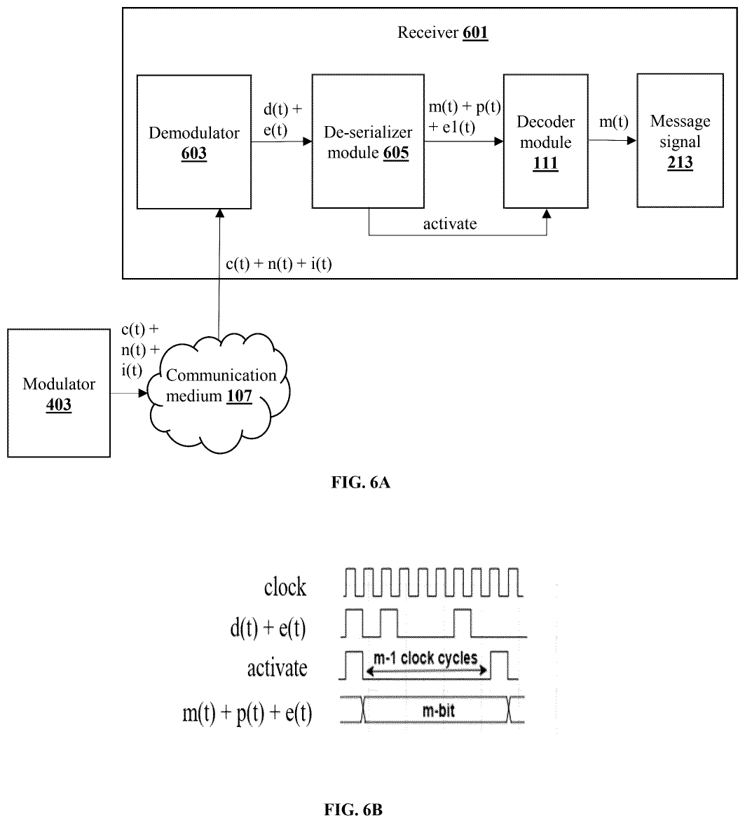

FIG. 6A illustrates an internal hardware architecture of a receiver 601 comprising at least one demodulator 603 and at least one de-serializer module 605, in accordance with an embodiment of the present disclosure. In an embodiment, the receiver 601 is similar to the receiver 105 of FIG. 1A, and the receiver 501 of FIG. 5. Further, in an embodiment, the at least one demodulator 603 is similar to the at least one demodulator 535 of FIG. 5. Furthermore, the at least one de-serializer module 605 is similar to the at least one de-serializer module 533 of FIG. 5.

In an embodiment, the receiver 601 may comprise at least one demodulator 603 configured to receive the modulated signal 221, represented as c(t), from the modulator 403 associated with the transmitter 401, through the communication medium 107. Further, the at least one demodulator 603 may be configured to receive a noise signal and interference signal from surroundings of the BAN. In an embodiment, the noise signal and the interference signal may be represented as shown in equation (8) and equation (9) respectively:

$$Noise signal = n ( t ) \qquad ( 8 )$$

$$Interference signal = i ( t ) \qquad ( 9 )$$

Further, the at least one demodulator 603 may be configured to create an output bitstream 523 by demodulating the modulated signal 221, the noise signal and the interference signal. In an embodiment, the output bitstream 523 may be represented as shown in equation (10):

$$Output bitstream = d ( t ) + e ( t ) , \qquad ( 10 )$$

$$where$$

$$e ( t ) represents the error signal 517$$

In an embodiment, since the human body 107a may pick up the noise signal, represented as n(t), and the interference signal, represented as i(t), the receiver 601 may capacitively sense and demodulate the noise signal and the interference signal by way of a demodulator 603, which may introduce the error signal 517, represented as e(t), at the output bitstream 523, represented as d(t)+e(t).

FIG. 6B illustrates the operation cycle of the at least one de-serializer module 605, in accordance with an embodiment of the present disclosure.

In an embodiment, the receiver 601 further comprises at least one de-serializer module 605 configured to determine number of bits present in the output bitstream 523, and dynamically activate the decoder module 111 in third set of cycle operations, based on the determined number of bits. Further, the at least one de-serializer module 605 may be configured to dynamically de-deactivate the decoder module 111 in fourth set of cycle operations, for generating a de-serialized bit stream 521, based on the determined number of bits. In an embodiment, the third set of cycle operations may comprise at least a first cycle and the fourth set of cycle operations may comprise at least remaining cycles excluding the first cycle, in which the sum of the third set of cycle operations and the fourth set of cycle operations may correspond to total number of bits present in the output bitstream 523.

For example, the de-serializer module 605 may take ‘m’ clock cycles to de-serialize the m-bit data present in the output bitstream 523. Since the decoder module 111 may process m-bit symbol per clock cycle, the de-serializer module 605 may activate the decoder module 111 for a single cycle and may deactivate the decoder module 111 for rest of the m−1 clock cycles.

In an embodiment, the de-serialized bitstream 521 may be represented as shown in equation (11):

$$De - serialized bitstream = m ( t ) + p ( t ) + e 1 ( t ) , \qquad ( 11 )$$

$$Where$$

$$e 1 ( t ) represents subset of the error signal 517$$

Finally, the at least one de-serializer module 605 may be configured to convert the output bitstream 523 into the one or more data symbols based on the generated de-serialized bit stream 521.

In an embodiment, the output bitstream 523 may pass through the de-serializer module 605 for generating a plurality of data symbols for the decoder module 111, where each symbol may consist of n-bit information. For example, but not limited to, if the number of non-zero error signal 517, represented as e(t)={e₁, e₂, . . . , eₖ, . . . , eₖ₊₂ₜ} is less than or equal to ‘t’, the decoder module 111 may recover the corrupted symbols, and the original message signal 213, represented as m(t), may be reconstructed at the receiver 601.

Finally, the message signal 213 may be finally sent to the receiver processor 503 if further processing on the data is required or may be sent to display (not shown in FIG. 6A) of the communication system 101, for visualization if the message signal 213 contains image or video data. Furthermore, in an embodiment, the message signal 213 may be sent to headsets if the message signal 213 contains audio data.

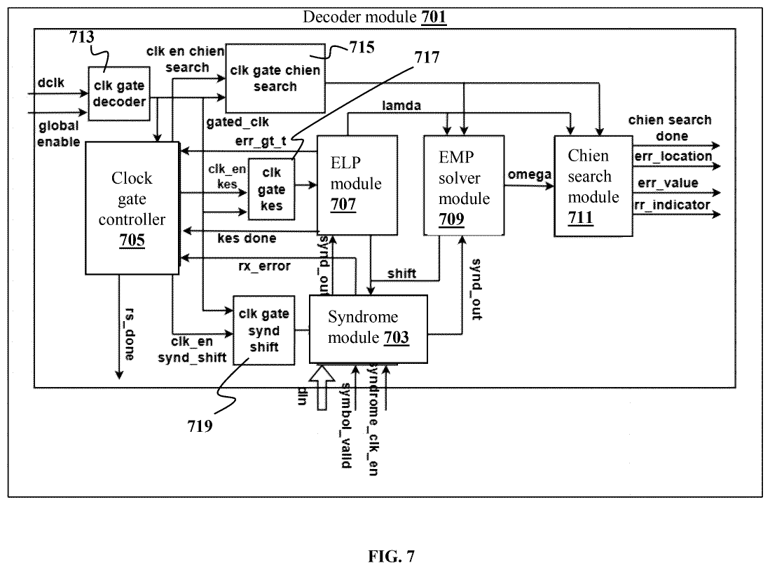

FIG. 7 illustrates an internal hardware architecture of a decoder module 701, in accordance with an embodiment of the present disclosure. In an embodiment, the decoder module 701 is similar to the decoder module 111 of FIG. 1A.

In an embodiment, as shown in FIG. 7, the decoder module 701 may comprise at least one syndrome module 703, at least one clock gate controller 705, an Error Location Polynomial (ELP) module 707, an Error Magnitude Polynomial (EMP) solver module 709, and a Chien search module 711. In an embodiment, the at least one syndrome module 703 is similar to the at least one syndrome module 113 of FIG. 1A. Further, the at least one clock gate controller 705 is similar to the at least one clock gate controller 115 of FIG. 1A.

In an embodiment, the ELP module 707 is similar to the ELP module 527 of FIG. 5. Further, in an embodiment, the EMP solver module 709 is similar to the EMP solver module 529 of FIG. 5. Furthermore, in an embodiment, the Chien search module 711 is similar to the Chien search module 531 of FIG. 5.

In an embodiment, the at least one syndrome module 703 may be configured to calculate one or more syndrome values 515 for the received one or more encoded data symbols 513. In an embodiment, the number of one or more syndrome values 515 may be proportional to twice maximum error correction capacity value of the one or more encoded data symbols 513. Further, the at least one syndrome module 703 may be configured to generate an error signal 517 when the calculated one or more syndrome values 515 corresponds to a non-zero value.

In an embodiment, the at least one clock gate controller 705 may be configured to receive the error signal 517 from the at least one syndrome module 703, and may activate the Error Location Polynomial (ELP) module 707 when the error signal (rx_error) 517 from the at least one syndrome module 703 goes high. In an embodiment, the ELP module may include, for example, but not limited to, a Berlekamp Massey key equation solver module. Further, the at least one clock gate controller 705 may be configured to generate an error indication signal 519, based on the activated ELP module 707. In an embodiment, the error indication signal 519 may correspond to number of errors present in the one or more encoded data symbols 513. Furthermore, the at least one clock gate controller 705 may activate the Error Magnitude Polynomial (EMP) solver module 709 and a chien search module 711 based on determining polarity of the error indication signal 519. Finally, the at least one clock gate controller 705 may be configured to decode the one or more encoded data symbols 513 based on the activated EMP solver module 709 and the chien search module 711.

Furthermore, in an embodiment, a clock gate decoder 713, the clock gate controller 705, a clock gate Chien search 715, a clock gate kes 717, and a clock gate synd shift module 719 may provide one or more activation and deactivation signals for different modules of the decoder module 111. In an embodiment, the clock gate decoder 713 may be configured to deactivate clock operation of the decoder module 701 upon completion of the decoding process.

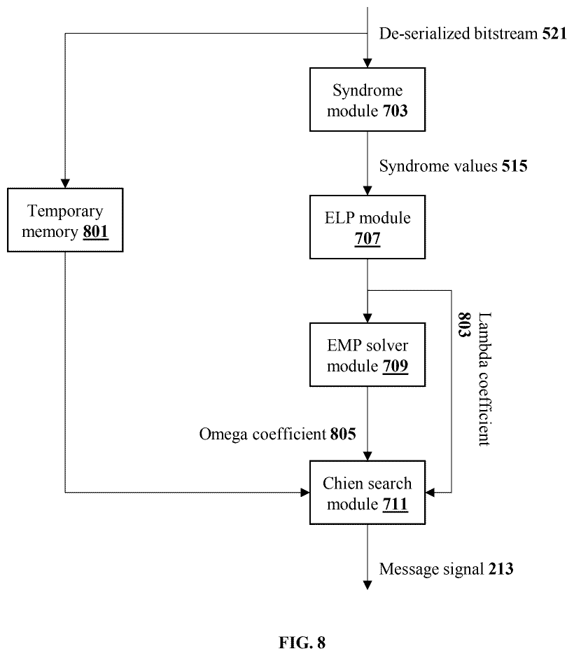

FIG. 8 illustrates an exemplary representation of a dataflow in the decoder module 701, as shown in FIG. 7, in accordance with an embodiment of the present disclosure.

In an embodiment, as illustrated in FIG. 8, the deserialized bitstream 521 may go to the syndrome module 703 and a temporary memory 801. Further, the syndrome module 703 may generate one or more syndrome values 515, when the decoder module 701 receives all the data. Furthermore, the one or more syndrome values 515 may go through the ELP module 707, and the EMP solver module 709, in which the ELP module 707 and the EMP solver module 709 may produce one or more polynomial coefficients to detect the error location and correct the corrupted one or more encoded data symbols 513. In an embodiment, the one or more polynomial coefficients produced by the ELP module 707 may include, for example, a lambda coefficient 803. Further, in an embodiment, the one or more coefficients produced by the EMP solver module 709 may include, for example, but not limited to, an omega coefficient 805 (as shown in FIG. 8).

Finally, if the number of errors in the received message is within the correctable limits, corrected message may come out from the decoder module 701. In an embodiment, the corrected message may correspond to the message signal 213, which may be originally transmitted from the transmitter 103. Further, in an embodiment, during error correction, the Chien search module 711 may read the corrupt data the temporary memory 801 and may store it back to the temporary memory 801 after correction.

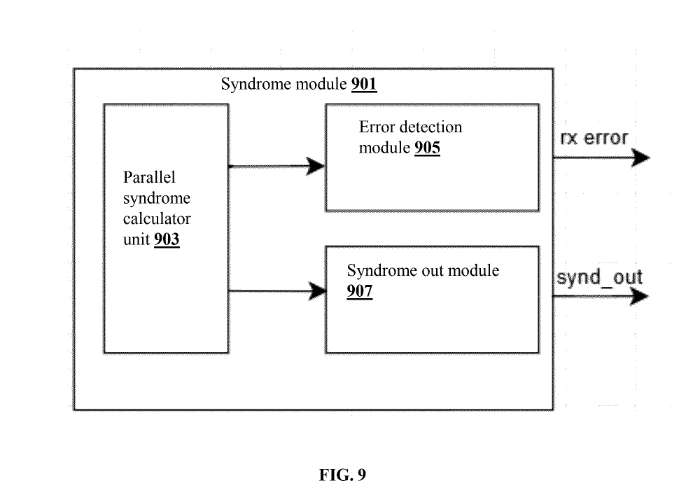

FIG. 9 illustrates an internal hardware architecture of a syndrome module 901, in accordance with an embodiment of the present disclosure. In an embodiment, the syndrome module 901 is similar to the syndrome module 113 of FIG. 1A, and the syndrome module 703 of FIG. 7.

In an embodiment, as shown in FIG. 9, the syndrome module 901 may comprise a parallel syndrome calculator unit 903, an error detection module 905, and a syndrome out module 907.

In an embodiment, the parallel syndrome calculator unit 903 further comprises a Galois adder and a constant multiplier. The parallel syndrome calculator unit 903 may be configured to receive the deserialized bit stream from the at least one de-serializer module 605 associated with the receiver 601. Further, the parallel syndrome calculator unit 903 may generate the one or more syndrome values 515 using the Galois adder and the constant multiplier, and may store the one or more syndrome values 515 in a flip flop module (not shown in FIG. 9). In an embodiment, the flip flop module may include, for example, but not limited to, a D flip flop module.

In an embodiment, the error detection module 905 may receive each of the generated one or more syndrome values 515 from the parallel syndrome calculator unit 903, and may perform logical OR operation on each of the one or more syndrome values 515. Further, the error detection module 905 may be configured to generate an error signal (rx error) (also referred as rx_error) 517 when the generated one or more syndrome values 515 corresponds to a non-zero value.

Further, in an embodiment, the syndrome out module 907 may be configured to activate upon receiving the error signal (rx error) 517 from the error detection module 905, through the at least one clock gate controller 705 (as shown in FIG. 7).

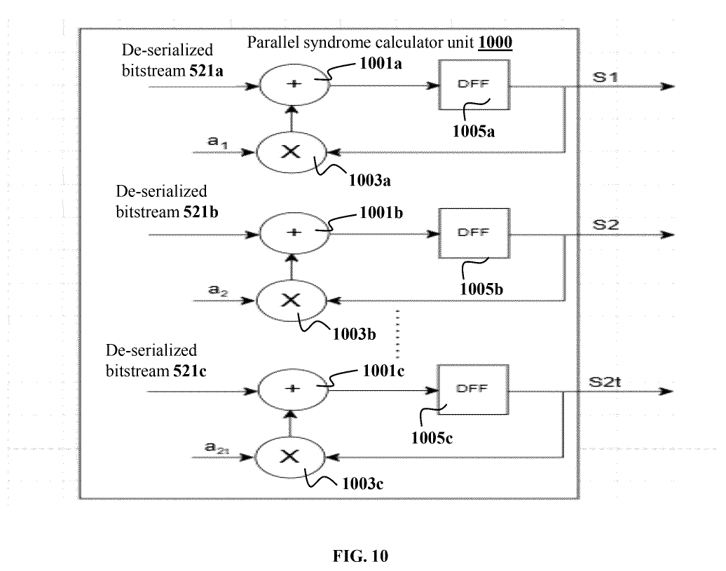

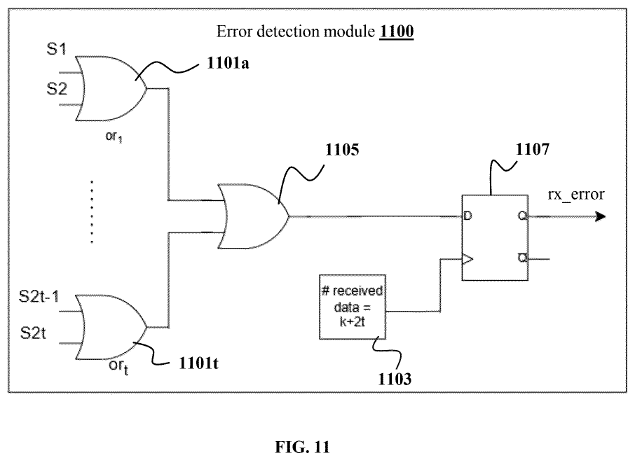

FIG. 10 illustrates an internal hardware architecture of a parallel syndrome calculator unit 1000, in accordance with an embodiment of the present disclosure. In an embodiment, the parallel syndrome calculator unit 1000 is similar to the parallel syndrome calculator unit 903 of FIG. 9.

In an embodiment, as shown in FIG. 10, the parallel syndrome calculator unit 903 may comprise a Galois adder (1001a, 1001b, 1001c) and a constant multiplier (1003a, 1003b, 1003c). The parallel syndrome calculator unit 1000 may be configured to receive the deserialized bit stream (521a, 521b, 521c) from the at least one de-serializer module 605 associated with the receiver 601. Further, the parallel syndrome calculator unit 1000 may generate the one or more syndrome values 515 using the Galois adder (1001a, 1001b, 1001c) and the constant multiplier (1003a, 1003b, 1003c), and may store the one or more syndrome values 515 in a flip flop module (1005a, 1005b, 1005c). In an embodiment, the flip flop module (1005a, 1005b, 1005c) may include, for example, but not limited to, a D flip flop module.

For example, the parallel syndrome calculator unit 1000 may calculate ‘2t’ syndromes in which ‘t’ may be the maximum error correction capacity of the decoder module 701. Once the receiver 601 processes k+2t symbols, the generation of the one or more syndrome values 515 may be done. This may be achieved using a counter. In an embodiment, the parallel syndrome calculator unit 1000 may generate one or more syndrome values 515, which may be represented as S1, S2, . . . S2t (as shown in FIG. 10). For example, the parallel syndrome calculator unit 1000 may receive the deserialized bit stream 521a from the at least one de-serializer module 605 associated with the receiver 601. Further, the parallel syndrome calculator unit 1000 may generate the syndrome value S1 using the Galois adder 1001a and the constant multiplier 1003a, and may store the syndrome value S1 in the flip flop module 1005a.

FIG. 11 illustrates an internal hardware architecture of an error detection module 1100, in accordance with an embodiment of the present disclosure. In an embodiment, the error detection module 1100 is similar to the error detection module 905 of FIG. 9.

In an embodiment, the error detection module 1100 may receive each of the generated one or more syndrome values 515 from the parallel syndrome calculator unit 1000, and may perform logical OR operation on each of the one or more syndrome values 515. Further, the error detection module 1100 may be configured to generate an error signal (rx_error) 517 when the generated one or more syndrome values 515 corresponds to a non-zero value.

For example, the error detection module 1100 (as shown in FIG. 11) may take the one or more syndrome values 515 i.e. S1, S2, S2t as input and may perform logical “OR” operation on the one or more syndrome values 515, using one or more OR logic gates such as 1101a . . . 1101t. For example, the OR logic gate 1101a may perform logical OR operation on the syndrome values S1, and S2. Once the number of received symbol reaches k+2t (as shown in block 1103), the error detection module 1100 may capture the final “OR” ed output. In an embodiment, the final “OR” ed output may be captured using a OR logic gate 1105 (as shown in FIG. 11). In an embodiment, the error detection module 1100 may generate the error signal (rx_error) 517 if one of the calculated first ‘t’ syndromes is non-zero. In other words, the error detection module 1100 may generate the error signal (rx_error) 517 by passing the final “OR” ed output into a flip flop module 1107 such as for example, but not limited to, a D-flip flop.

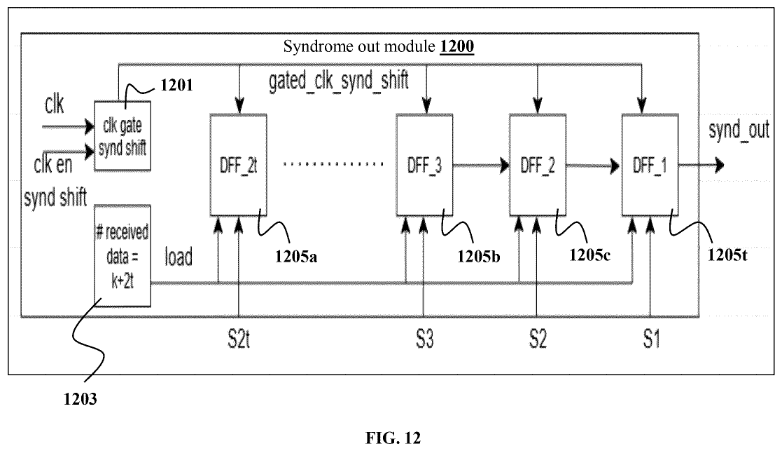

FIG. 12 illustrates an internal hardware architecture of a syndrome out module 1200, in accordance with an embodiment of the present disclosure. In an embodiment, the syndrome out module 1200 is similar to the syndrome out module 907 of FIG. 9.

In an embodiment, as shown in FIG. 12, the syndrome out module 1200 may consist of one or more parallel in serial out shift registers. When the count of the received signal crosses k+2t, the one or more syndrome values 515 may be loaded into the shift registers and shifted out serially one by one. The syndrome out module 1200 may comprise one or more flip flop modules such as for example, but not limited to, D-Flip Flops (DFFs). For example, as shown in FIG. 12, the one or more flip flop modules may include DFF_1 1203a, DFF_2 1203b, DFF_3 1203c, . . . DFF_2t 1203t. Further, the syndrome out module 1200 may include a counter 1203 which indicates that the number of received symbol is equal to k+2t generating the load signal. Once load signal goes high, all the syndrome values 515 may be loaded in the DFFs. Further, in an embodiment, a clock gate synd shift module 1205 may be configured to enable and disable the clock of the syndrome out module 1200 based on the clk_en signal.

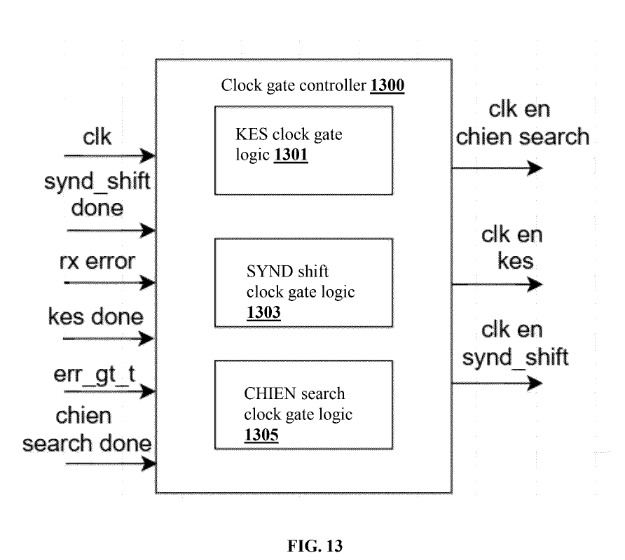

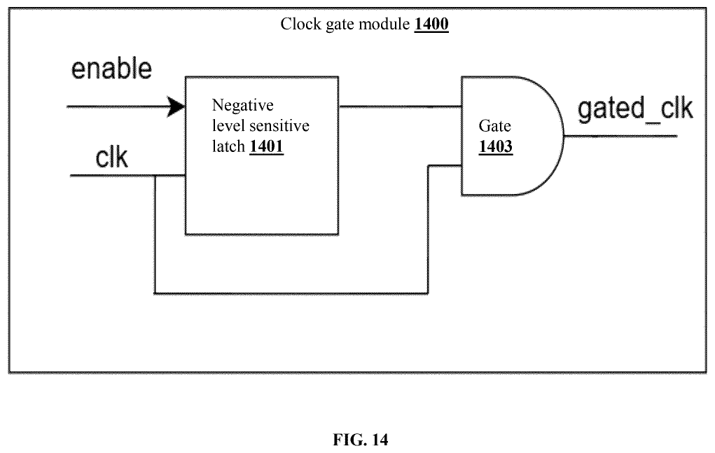

FIG. 13 illustrates an internal block diagram of at least one clock gate controller 1300, in accordance with an embodiment of the present disclosure. In an embodiment, the at least one clock gate controller 1300 is similar to the at least one clock gate controller 705 of FIG. 7.

In an embodiment, as shown in FIG. 13, the at least one clock gate controller 1300 may comprise a KES clock gate logic 1301, a SYND shift clock gate logic 1303, and a CHIEN search clock gate logic 1305. The at least one clock gate controller 1300 may receive one or more signals such as an error signal (rx_error) 517, an error indication signal (err_gt_t) 519, a shift terminate signal (synd_shift_done), an error terminate signal (kes_done), a chien search terminate signal (chien_search_done) as inputs and generates one or more signals such as clk_en_chien_search, clk_en_kes, clk_en_synd_shift as output. Further, in an embodiment, the KES clock gate logic 1301 may receive the error signal (rx_error) 517, and the error terminate signal (kes_done) as input and produces clk_en_kes signal which may further enable and disable the clock of the ELP module 707.

In an embodiment, the SYND_shift_clock_gate logic 1303 may receive the error signal (rx_error) 517, and the shift terminate signal (synd_shift_done) as input and generates clk_en_synd_shift signal, which may further enable and disable the clock of syndrome out module 1200. Likewise, the CHIEN search clock gate logic 1305 may receive the error indication signal (err_gt_t) 519, and the chien search terminate signal (chien_search_done) as input and may further control the enable and disable signal of the EMP solver module 709 and the chien search module 711.

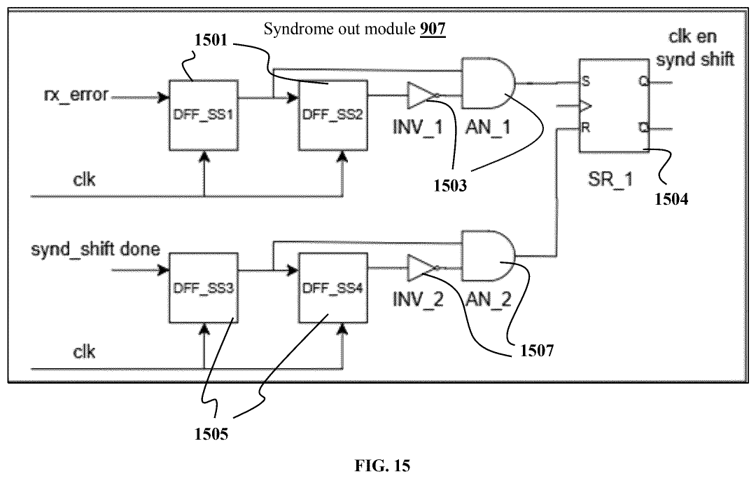

FIG. 14 illustrates a generic block diagram of a clock gate module 1400, in accordance with an embodiment of the present disclosure.

In an embodiment, as shown in FIG. 14, the clock gate module 1400 may comprise a negative level sensitive latch 1401 and an AND gate 1403. Further, in an embodiment, when an enable signal is high, the clock module 1400 passes the clock to propagate through the negative level sensitive latch 1401. Furthermore, if the enable signal is low, the clock module 1400 stops the clock from propagating.

In an embodiment, the clock gate module 1400 may include, for example, but not limited to, the clock gate decoder 713, the clock gate chien search 715, the clock gate kes 717, the clock gate synd shift 719 (as shown in FIG. 7).

FIG. 15 illustrates an exemplary representation of clock enable signal generation in the syndrome out module 907, as shown in FIG. 9, in accordance with an embodiment of the present disclosure.

In an embodiment, the syndrome out module 907 may be configured to detect a rising edge of the error signal (rx_error) 517 received from the error detection module 905, using first set of flip flop modules 1501 and first set of logic gates 1503 associated with the syndrome out module 907. Further, the syndrome out module 907 may be configured to set a latch module (SR_1) 1504 based on the detected rising edge, to enable the clock (clk en synd shift) associated with the syndrome out module 907. Furthermore, the syndrome out module 907 may generate a shift terminate signal (synd_shift done), based on the enabled clock, when the one or more syndrome values 515 are shifted out serially. Furthermore, the syndrome out module 907 may be configured to detect rising edge of the generated shift terminate signal (synd_shift done), using second set of flip flop modules 1505 and second set of logic gates 1507 associated with the syndrome out module 907. Finally, the syndrome out module 907 may reset the latch module (SR_1) 1504 based on the detected rising edge, to disable operation of the syndrome out module 907. In an embodiment, the first set of flip flop modules 1501 and the second set of flip flop modules 1505 associated with the syndrome out module 907 may comprise at least one of D-flip flop module. Further, in an embodiment, the first set of logic gates 1503 and the second set of logic gates 1507 associated with the syndrome out module 907 may comprise at least one of a NOT gate, an OR gate, and an AND gate.

For example, the syndrome out module 907 may sense the rising edge of the error signal (rx_error) 517 using the first set of flip flop modules 1501 such as DFF_SS1, and DFF_SS2, and the first set of logic gates 1503 such as INV_1, and AN_1. Further, the rising edge signal may set the set the latch module (SR_1) 1504 which may further enable the clock of the syndrome out module 907. Furthermore, the shift terminate signal (synd_shift done) may go high if all the one or more syndrome values 515 are shifted out serially.

In an embodiment, the syndrome out module 907 may also detect the rising edge of shift terminate signal (synd_shift done) using the second set of flip flop modules 1505 such as DFF_SS3, and DFF_SS4, and second set of logic gates 1507 such as INV_2, and AN_2 to reset the latch module (SR_1) 1504 which may further disable the syndrome out module 907. This may lead to lower energy dissipation of the decoder module 701.

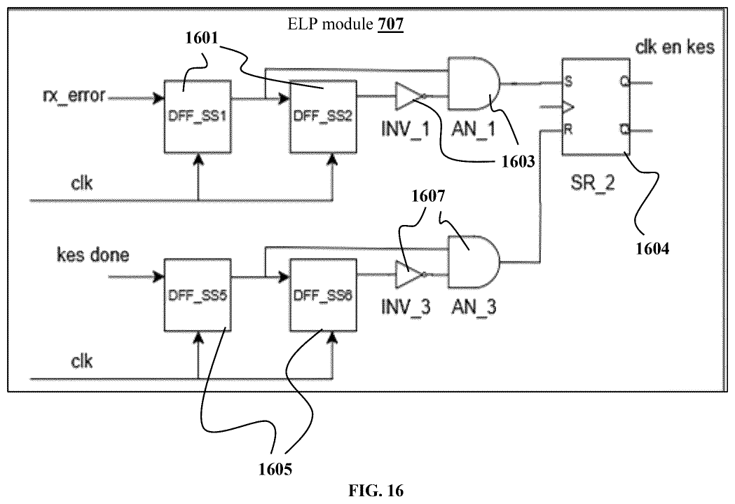

FIG. 16 illustrates an exemplary representation of clock enable signal generation in the Error Location Polynomial (ELP) module 707, as shown in FIG. 7, in accordance with an embodiment of the present disclosure.

In an embodiment, the ELP module 707 may be configured to detect rising edge of the error signal (rx_error) 517 received from the syndrome module 901, using first set of flip flop modules 1601 and first set of logic gates 1603 associated with the ELP module 707. Further, the ELP module 707 may be configured to set a latch module (SR_2) 1604 based on the detected rising edge, to enable the clock (clk en kes) associated with the ELP module 707. Furthermore, the ELP module 707 may generate an error terminate signal (kes done) based on the enabled clock. Furthermore, the ELP module 707 may be configured to detect rising edge of the error terminate signal (kes done), using second set of flip flop modules 1605 and second set of logic gates 1607 associated with the ELP module 707. Finally, the ELP module 707 may reset the latch module (SR_2) 1604 based on the detected rising edge, to disable operation of the ELP module 707.

For example, the ELP module 707 may detect the rising edge of the error signal (rx_error) using the first set of flip flop modules 1601 such as DFF_SS1, and DFF_SS2, and the first set of logic gates 1603 such as INV_1, and AN_1. Further, the rising edge signal may set the SR latch (SR_2) 1604 which may further enable the clock (clk en kes) of the ELP module 707. Once the ELP module 707 calculation is done, the ELP module 707 may generate the error terminate signal (kes done).

Further, in an embodiment, the ELP module 707 may detect the rising edge of the error terminate signal (kes done) using the second set of flip flop modules 1605 such as DFF_SS5, and DFF_SS6, and the second set of logic gates 1607 such as INV_3, and AN_3. Furthermore, the rising edge signal may reset the SR latch (SR_2) 1604. This may lower the power consumption of the ELP module 707. In other words, if the error signal (rx_error) is low, the whole operation of the decoder module 701 may be stopped as there is no error in the received signal.

Further, in an embodiment, the ELP module 707 may be configured to generate one or more polynomial coefficients based on the activation, in which the one or more polynomial coefficient comprises at least one of a lambda coefficient 803. Further, the ELP module 707 may detect location of error present in the one or more data symbols 513, based on the generated one or more polynomial coefficients. Finally, the ELP module may be configured to rectify one or more errors in the one or more data symbols 513 based on the detected location. In an embodiment, the first set of flip flop modules 1601 and the second set of flip flop modules 1605 associated with the ELP module 707 may comprise at least one of D-flip flop modules, and the first set of logic gates 1603 and the second set of logic gates 1607 associated with the ELP module 707 may comprise at least one of a NOT gate, an OR gate, and an AND gate.

For example, the ELP module 707 may output a lambda coefficient 803 along with an error indication signal (error_gt_t) 519 indicating errors in the received signal greater than or equal to ‘t’. Furthermore, the at least one clock gate controller 705 may sense the error indication signal (error_gt_t) 519 signal and may further enable the EMP solver module 709 and the chien search module 711 based on the polarity of the sensed signal.

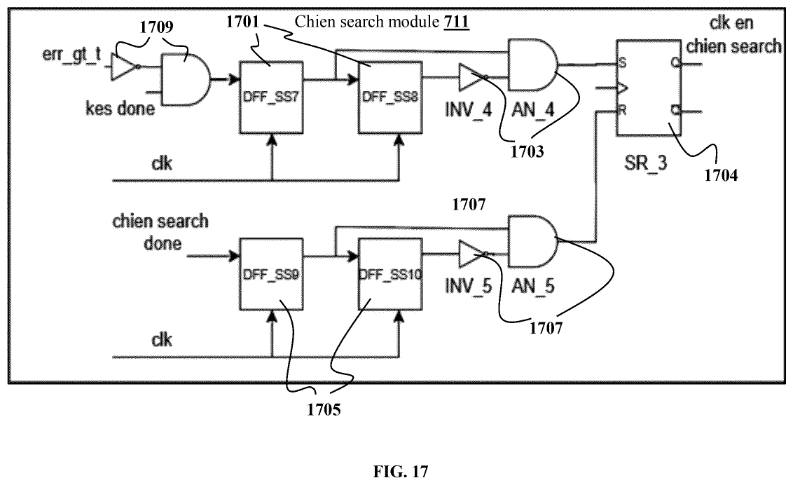

FIG. 17 illustrates an exemplary representation of clock enable signal generation in the chien search module 711, as shown in FIG. 7, in accordance with an embodiment of the present disclosure.

In an embodiment, the chien search module 711 may be configured to detect rising edge of the error terminate signal (kes done) received from ELP module 707, using first set of flip flop modules 1701 and first set of logic gates 1703 associated with the chien search module 711. Further, the chien search module 711 may be configured to set a latch module (SR_3) 1704 based on the detected rising edge, to enable the clock (clk en chien search) associated with the ELP module 707. Furthermore, the chien search module 711 may generate a chien search terminate signal (chien search done) based on the enabled clock, and may detect rising edge of the chien search terminate signal (chien search done), using second set of flip flop modules 1705 and second set of logic gates 1707 associated with the chien search module 711. Finally, the chien search module 711 may be configured to reset the latch module (SR_3) 1704 based on the detected rising edge, to disable operation of the chien search module 711. In an embodiment, the first set of flip flop modules 1701 and the second set of flip flop modules 1705 associated with the chien search module 711 may comprise at least one of D-flip flop modules, and the first set of logic gates 1703 and the second set of logic gates 1707 associated with the chien search module 711 may comprise at least one of a NOT gate, an OR gate, and an AND gate.

For example, if the error indication signal (error_gt_t) 519 is low, which may be sensed using logic gates 1709 (as shown in FIG. 17), the rising edge of the error terminate signal (kes done) may set the latch module (SR_3), which may make the clock signal (clk en chien search) high. Once chien search calculation goes high, the chien search module 711 may sense rising edge of the chien terminate signal (chien search done) to reset the latch module (SR_3). This may lower the energy dissipation of the decoder module 701. More specifically, the first set of flip modules 1701 may include DFF_SS7, and DFF_SS8, and the first set of logic gates 1703 may include INV_4, and AN_4, which may be used to detect the rising edge of the error terminate signal (kes done). Likewise, the second set of flip flop modules 1705 such as DFF_SS9, and DFF_SS10, and the second set of logic gates 1707 such as INV_5, and AN_5 may be used to detect the rising edge of the chien terminate signal (chien search done).

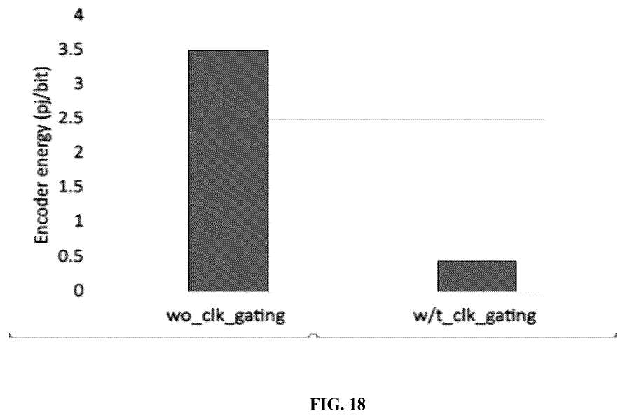

FIG. 18 illustrates an exemplary graphical representation of an estimated energy per bit of the encoder module 109 with and without clock gating, in accordance with an embodiment of the present disclosure.

FIG. 18 shows the estimated energy per bit of the encoder module 109 such as an RS encoder module, with and without clock gating in TSMC65 nm technology using Synopsys physical design tool. The energy may be estimated for m=8 (RS (255,233)) at the routing stage of physical design flow. As shown in FIG. 18, without clock gating, the encoder module 109 such as for example, but not limited to, the Reed Solomon (RS) encoder may receive around 3.5 pj/bit energy, whereas with the proposed error proportional energy saving in encoder module 109 may takes around 0.44 pj/bit energy. Hence, an 8× energy saving may be achieved using properly clocking the encoder module 109, when the serializer module 303 generates serialized bit stream 219.

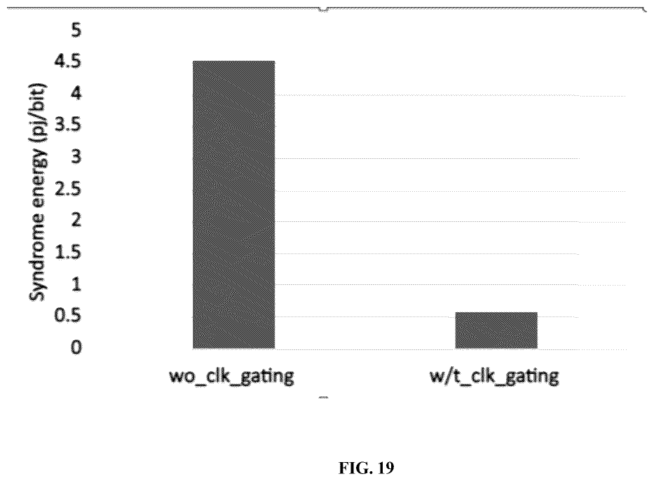

FIG. 19 illustrates an exemplary graphical representation of an estimated energy per bit of the syndrome module 113 with and without clock gating, in accordance with an embodiment of the present disclosure.

FIG. 19 shows the estimated energy per bit of the syndrome module 113 with and without clock gating in TSMC65 nm technology using Synopsys physical design tool. The energy may be estimated for m=8 (RS (255,233)) at the routing stage of physical design flow. As shown in FIG. 19, without clock gating the decoder module 111 such as for example, but not limited to, a Reed Solomon (RS) decoder modules may receive around 4.5 pj/bit energy, whereas with the proposed error proportional energy saving in the decoder module 111 takes around 0.56 pj/bit energy. Hence, an 8× energy saving may be achieved using properly clock gating syndrome module 113 when the serializer module 303 generates serialized bit stream 219.

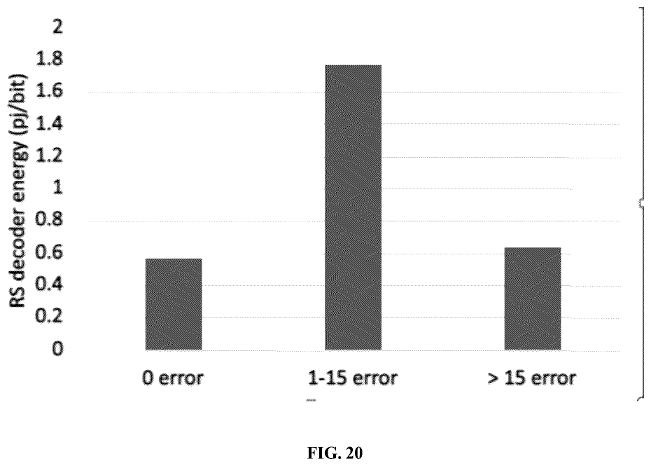

FIG. 20 illustrates an exemplary graphical representation of an estimated energy per bit of the decoder module 111 for one or more different errors, in accordance with an embodiment of the present disclosure.

FIG. 20 shows the estimated energy per bit of the decoder module 111 such as a RS decoder module for different error scenarios in TSMC65 nm technology using Synopsys physical design tool. The energy may be estimated for m=8 (RS (255,233)), and t=16 at the routing stage of the physical design flow. As shown in FIG. 20, at the point of no error (0 error) the energy dissipation of the RS decoder may be minimum, around 0.58 pj/bit, and the energy dissipation may be maximum, around 1.8 pj/bit, when 1-15 errors occurred in the received symbols. Since the decoding process may be terminated when the number of errors is greater than 15, the EMP solver module 709 and the chien search module 711 may be disabled, in which the energy dissipation may be lower in the case of 1-15 errors.

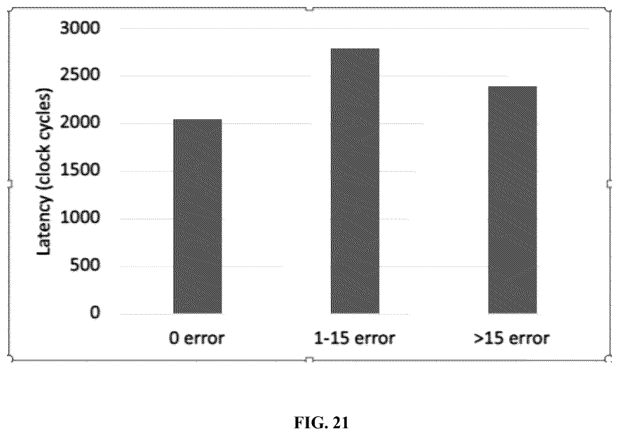

FIG. 21 illustrates an exemplary graphical representation of latency of the decoder module 111 for one or more different errors, in accordance with an embodiment of the present disclosure.

FIG. 21 shows the latency of the decoder module 111 such as the RS decoder module for different error scenarios in TSMC65 nm technology using Synopsys physical design tool. The latency may be estimated for m=8 (RS (255,233)), and t=16. If there is no error (0 error) in the received data, the latency may be 2040 cycles which may be due to the data deserialization and syndrome calculation. Further, when 1-15 errors are occurred in the received symbols, all the modules may be enabled in the decoder pipeline and the latency is the highest 2784 cycles. However, when there is more than 15 errors in the received data, the ELP module 707 may disable the EMP solver module 709 and the chien search module 711 which may take 2392 clock cycles to execute.

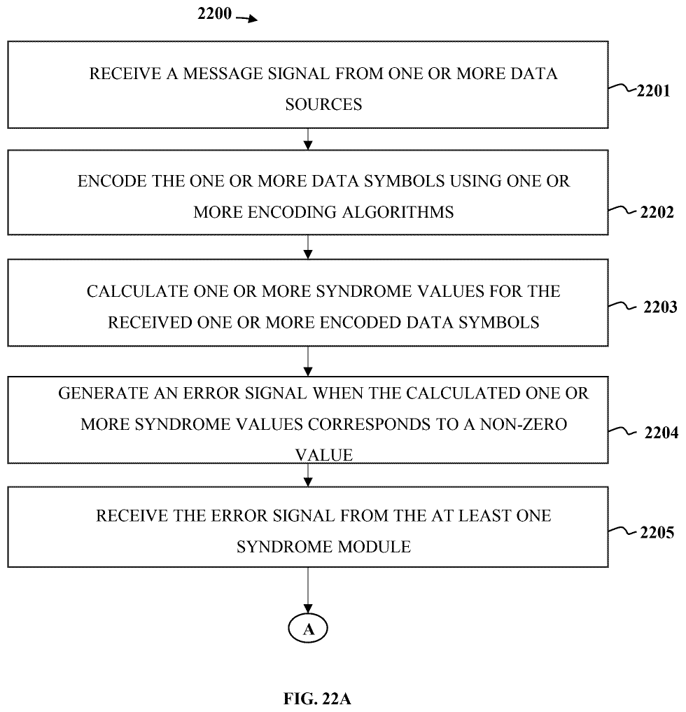

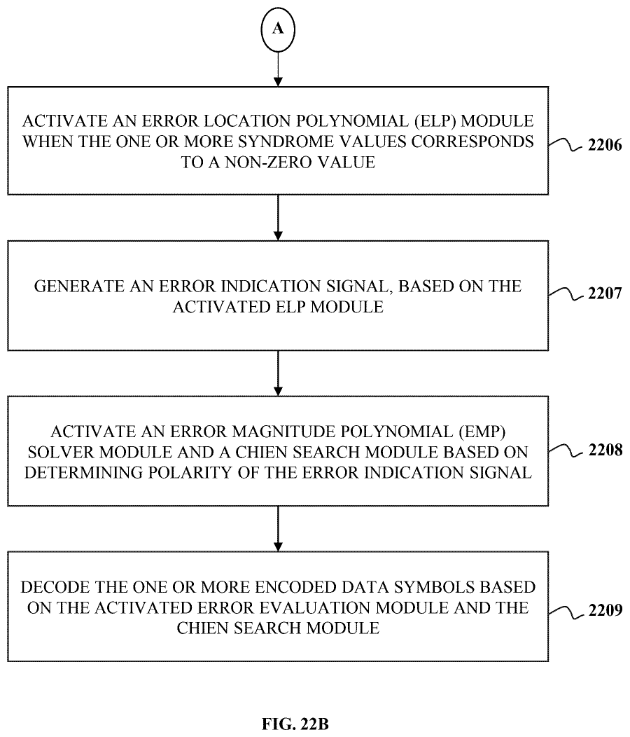

FIGS. 22A-22B illustrates a flow chart representation of method 2200 for error-proportional energy-saving in encoding and decoding in Body Area Networks (BAN) using Human Body Communication (HBC), in accordance with an embodiment of the present disclosure.

At step 2201, the method 2200 includes receiving, by an encoder module 109, a message signal 213 from one or more data sources. In an embodiment, the message symbol 213 may comprise one or more data symbols.

At step 2202, the method 2200 includes encoding, by the encoder module 109, the one or more data symbols using one or more encoding algorithms. In an embodiment, the one or more encoding algorithms may include, for example, but not limited to, a RS encoding algorithm.

At step 2203, the method 2200 includes calculating, by at least one syndrome module 113, one or more syndrome values 515 for the received one or more encoded data symbols 513. In an embodiment, the number of one or more syndrome values 515 may be proportional to twice maximum error correction capacity value of the one or more encoded data symbols 513.

At step 2204, the method 2200 includes generating, by the at least one syndrome module 113, an error signal 517 when the calculated one or more syndrome values 515 corresponds to a non-zero value.

At step 2205, the method 2200 includes receiving, by at least one clock gate controller 115, the error signal 517 from the at least one syndrome module 113.

At step 2206, the method 2200 includes activating, by the at least one clock gate controller 115, an Error Location Polynomial (ELP) module 707 when the one or more syndrome values 515 corresponds to a non-zero value.

At step 2207, the method 2200 includes generating, by the at least one clock gate controller 115, an error indication signal 519, based on the activated ELP module 707. In an embodiment, the error indication signal 519 may correspond to number of errors present in the one or more encoded data symbols 513.

At step 2208, the method 2200 includes activating, by the at least one clock gate controller 115, an Error Magnitude Polynomial (EMP) solver module 709 and a chien search module 711 based on determining polarity of the error indication signal 519.

At step 2209, the method includes decoding, by the at least one clock gate controller 115, the one or more encoded data symbols 513 based on the activated EMP solver module 709 and the chien search module 711.

The order in which the method 2200 is described is not intended to be construed as a limitation, and any number of the described method blocks may be combined or otherwise performed in any order to implement the method 2200 or an alternate method. Additionally, individual blocks may be deleted from the method 2200 without departing from the spirit and scope of the ongoing description. Furthermore, the method 2200 may be implemented in any suitable hardware, software, firmware, or a combination thereof, that exists in the related art or that is later developed. The method 2200 describes, without limitation, the implementation of the communication system 101 for error-proportional energy-saving in encoding and decoding in Body Area Networks (BAN) using Human Body Communication (HBC). A person of skill in the art will understand that method 2200 may be modified appropriately for implementation in various manners without departing from the scope and spirit of the ongoing description.

The present disclosure facilitates the use of an energy-adaptive encoding module and a decoding module for a Human Body Communication (HBC) that opportunistically saves energy when the HBC channel is either very good or very bad, lowering the overall consumed energy on average.

Further, the present disclosure increases the efficiency of the encoding and decoding process, thus reducing the power consumption of the one or more modules equipped during encoding and decoding process.

The communication system for error proportional energy saving of encoder module and the decoder module in Human Body Communication (HBC), of the present disclosure facilitates the use of an HBC transceiver, comprised of an HBC transmitter and an HBC receiver, which exploits the property of the bit-serial communication link of the HBC transceiver. Further the communication system of the present disclosure employs the multi-bit symbol of Reed Solomon (RS) forward error correction implementation to achieve an energy-efficient encoder module and decoder module for HBC network.

The transmitter of the present disclosure utilizes encoder module such as RS encoder to encode transmitted signal which travels through the human body and gets picked by HBC receiver which further has decoder module such as RS decoder to decode the received signal. Further, the encoder module and the decoder module of the present disclosure utilizes error proportional energy scaling of Reed Solomon in conjunction with HBC to achieve the lowest possible power consumption.

Further, the HBC transceiver of the present disclosure experiences burst error in interference dominated scenarios, further exploiting RS for efficient feedforward error correction.

Moreover, the encoder module of the present disclosure processes m-bits symbol in a single clock cycle, remains idle for m−1 clock cycles and waits for m-bits to be sent for modulation by the HBC transmitter's physical layer serially. Furthermore, the encoder module calculates the parity in a single cycle and clock gates the parity calculation module for m−1 clock cycles to save power. More specifically, the encoder module of the present disclosure senses the transmission done signal from transmitter to power gate the parity calculation module to save power.

Further, the present disclosure facilitates the use a syndrome module, which further utilizes the property of the bit-serial communication link of the HBC transceiver and the multi-bit symbol of Reed Solomon (RS) forward error correction implementation to achieve an energy-efficient RS encoder and RS decoder for HBC network. More specifically, the syndrome module processes m-bits symbol in a single clock cycle, remains idle for m−1 clock cycles and waits for m-bits to be received by the HBC receiver's physical layer serially. Further, the syndrome module of the present disclosure processes m-bits received data in a single clock cycle and is clock gated for m−1 clock cycles to save power.

Further the decoder module of the present disclosure employs an Error Location Polynomial (ELP) module such as an inversion-less Berlekamp-Massey key equation solver, an Error Magnitude Polynomial (EMP) solver module, a Chien search module, and clock gate controller, to achieve error proportional energy savings by dynamic clock and power gating of different modules of the decoder module pipelined implementation. The syndrome module indicates errors in the received symbols if one of the calculated syndromes is non-zero. Further, the clock gate controller of the present disclosure senses the syndrome done signal from syndrome module to power gate syndrome module to save power. More specifically, the clock gate controller samples the syndrome module's output indicating errors in the received symbols and enables the ELP module if errors happened in the received symbols, and otherwise power gate the EMP solver module to save power.

The ELP module of the present disclosure enables indication of the number of errors in the received symbols and errors greater than or equal to t, where t is the error correction capability of the decoder module. Further, the clock gate controller of the present disclosure senses the ELP module's output to enable the EMP solver module if the number of errors in the received symbols is less than or equal to t−1, and otherwise clock gates rest of the modules such as Chien search module to save power. More specifically, the clock gate controller of the present disclosure senses the signal of the ELP module to save power accordingly.

The present disclosure also enables the clock gate controller to sense the EMP solver module signal to save power accordingly. Similarly, the clock gate controller also senses the Chien search module signal to save power accordingly.

The present disclosure describes a system designed for error-proportional energy saving in Reed Solomon (RS) encoder and decoder components within a Human Body Communication (HBC) system. This system aims to improve energy efficiency in RS encoding and decoding, particularly for HBC applications, by intelligently managing power based on the real-time needs of the communication process and the error correction requirements.

The proposed system utilizes dynamic clock gating to save energy during transmission and reception of the information through human body. The energy consumption of the RS encoder and decoder have been estimated at the routing stage of physical design flow using Synopsys physical design tool in TSMC65 nm technology process.

The proposed design demonstrates 8× energy efficiency gains achieved through clock gating techniques during RS encoding and syndrome calculation of RS decoding processes. It also captures the relationship between energy consumption and the number of errors in RS decoding, showcasing the trade-offs between energy efficiency and error correction capability.

One of the ordinary skills in the art will appreciate that techniques consistent with the present disclosure are applicable in other contexts as well without departing from the scope of the disclosure.

What has been described and illustrated herein are examples of the present disclosure. The terms, descriptions, and figures used herein are set forth by way of illustration and are not meant as limitations. Many variations are possible within the spirit and scope of the subject matter, which is intended to be defined by the following claims and their equivalents in which all terms are meant in their broadest reasonable sense unless otherwise indicated.

The written description describes the subject matter herein to enable any person skilled in the art to make and use the embodiments. The scope of the subject matter embodiments is defined by the claims and may include other modifications that occur to those skilled in the art. Such other modifications are intended to be within the scope of the claims if they have similar elements that do not differ from the literal language of the claims or if they include equivalent elements with insubstantial differences from the literal language of the claims.

The embodiments herein may comprise hardware and software elements. The embodiments that are implemented in software include but are not limited to, firmware, resident software, microcode, a. The functions performed by various modules described herein may be implemented in other modules or combinations of other modules. For the purposes of this description, a computer-usable or computer-readable medium may be any apparatus that may comprise, store, communicate, propagate, or transport the program for use by or in connection with the instruction execution system, apparatus, or device.

A description of an embodiment with several components in communication with each other does not imply that all such components are required. On the contrary, a variety of optional components are described to illustrate the wide variety of possible embodiments of the invention. When a single device or article is described herein, it will be apparent that more than one device/article (whether or not they cooperate) may be used in place of a single device/article. Similarly, where more than one device or article is described herein (whether or not they cooperate), it will be apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments of the invention need not include the device itself.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries may be defined so long as the specified functions and relationships thereof are appropriately performed. Alternatives (including equivalents, extensions, variations, deviations, and the like, of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open-ended in that an item or items following any one of these words is not meant to be an exhaustive listing of such item or items or meant to be limited to the listed item or items. It must also be noted that as used herein and in the appended claims, the singular forms “a”, “an”, and “the” include plural references unless the context clearly dictates otherwise.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limited, of the scope of the invention, which is outlined in the following claims.

1. A communication system for error-proportional energy-saving in encoding and decoding in Body Area Networks (BAN) using Human Body Communication (HBC) comprising:
a transmitter comprising:
an encoder module configured to:
receive a message signal from one or more data sources, wherein the message symbol comprises one or more data symbols; and
encode the one or more data symbols using one or more encoding algorithms;
a receiver comprising:
a decoder module configured to receive the one or more encoded data symbols from the encoder module, wherein the decoder module further comprises:
at least one syndrome module configured to:
calculate one or more syndrome values for the received one or more encoded data symbols, wherein the number of one or more syndrome values is proportional to twice maximum error correction capacity value of the one or more encoded data symbols; and
generate an error signal when the calculated one or more syndrome values corresponds to a non-zero value;
at least one clock gate controller configured to:
receive the error signal from the at least one syndrome module;
activate an Error Location Polynomial (ELP) module when the one or more syndrome values corresponds to a non-zero value;
generate an error indication signal, based on the activated ELP module, wherein the error indication signal corresponds to number of errors present in the one or more encoded data symbols;
activate an Error Magnitude Polynomial (EMP) solver module and a chien search module based on determining polarity of the error indication signal; and
decode the one or more encoded data symbols based on the activated EMP solver module and the chien search module; and
a communication medium configured to:
establish communication sessions between the transmitter and the receiver; and
route the data between the transmitter and the receiver using the established communication sessions.

2. The communication system of claim 1, wherein the transmitter further comprises:
at least one serializer module configured to:
receive an appended signal from the encoder module associated with the transmitter, wherein the appended signal comprises the message signal and plurality of parity bits, wherein the plurality of parity bits are generated by the encoder module;
convert one or more data symbols present in the appended signal into an input bit stream;
determine number of bits present in the appended signal based on the generated input bit stream;
dynamically activate the encoder module in first set of cycle operations based on the determined number of bits; and
dynamically deactivate the encoder module in second set of cycle operations, for generating a serialized bit stream, based on the determined number of bits.

3. The communication system of claim 2, wherein the first set of cycle operations comprises at least a first cycle and the second set of cycle operations comprises at least remaining cycles excluding the first cycle, wherein the sum of the first set of cycle operations and the second set of cycle operations corresponds to total number of bits present in the input bitstream.

4. The communication system of claim 1, wherein the transmitter further comprises:
at least one modulator configured to:
receive the serialized bit stream from the at least one serializer module; and
convert the serialized bit stream into a modulated signal by modulating the serialized bit stream.

5. The communication system of claim 1, wherein the receiver further comprises:
at least one demodulator configured to:
receive the modulated signal from the modulator associated with the transmitter, through the communication medium;
receive a noise signal and interference signal from surroundings of the BAN; and
create an output bitstream by demodulating the modulated signal, the noise signal and the interference signal.

6. The communication system of claim 1, wherein the receiver further comprises:
at least one de-serializer module configured to:
determine number of bits present in the output bitstream;
dynamically activate the decoder module in third set of cycle operations, based on the determined number of bits;
dynamically de-deactivate the decoder module in fourth set of cycle operations, for generating a de-serialized bit stream, based on the determined number of bits; and
convert the output bitstream into the one or more data symbols based on the generated de-serialized bit stream.

7. The communication system of claim 6, wherein the third set of cycle operations comprises at least a first cycle and the fourth set of cycle operations comprises at least remaining cycles excluding the first cycle, wherein the sum of the third set of cycle operations and the fourth set of cycle operations corresponds to total number of bits present in the input bitstream.

8. The communication system of claim 1, wherein the message signal comprises at least one of an audio signal, a video signal, and an image signal.

9. The communication system of claim 1, wherein the decoding module further comprises a clock gate decoder configured to deactivate clock operation of the decoder module upon completion of the decoding process.

10. The communication system of claim 1, wherein the Error Magnitude Polynomial (EMP) solver module is configured to:
generate one or more polynomial coefficients based on the activation, wherein the one or more polynomial coefficient comprises at least one of a lambda coefficient;
detect location of error present in the one or more data symbols, based on the generated one or more polynomial coefficients; and
rectify one or more errors in the one or more data symbols based on the detected location.

11. The communication system of claim 1, wherein the decoder module is configured to disable the syndrome module when the one or more syndrome values corresponds to a zero value.

12. The communication system of claim 1, wherein the syndrome module further comprises:
a parallel syndrome calculator unit comprising a Galois adder and a constant multiplier, wherein the parallel syndrome calculator unit is configured to:
receive the deserialized bit stream from the at least one de-serializer module associated with the receiver; and
generate the one or more syndrome values using the Galois adder and the constant multiplier, and store the one or more syndrome values in a flip flop module;
an error detection module configured to:
receive each of the generated one or more syndrome values from the parallel syndrome calculator unit;
perform logical OR operation on each of the one or more syndrome values; and
generate an error signal when the generated one or more syndrome values corresponds to a non-zero value; and
a syndrome out module configured to activate upon receiving the error signal from the error detection module, through the clock gate controller.

13. The communication system of claim 12, wherein the syndrome out module is further configured to:
detect a rising edge of the error signal received from the error detection module, using first set of flip flop modules and first set of logic gates associated with the syndrome out module; and
set a latch module based on the detected rising edge, to enable the clock associated with the syndrome out module;
generate a shift terminate signal, based on the enabled clock, when the one or more syndrome values are shifted out serially;
detect rising edge of the generated shift terminate signal using second set of flip flop modules and second set of logic gates associated with the syndrome out module; and
reset the latch module based on the detected rising edge, to disable operation of the syndrome out module.

14. The communication system of claim 13, wherein the first set of flip flop modules and the second set of flip flop modules associated with the syndrome out module comprises at least one of D-flip flop modules, and wherein the first set of logic gates and the second set of logic gates associated with the syndrome out module comprises at least one of a NOT gate, an OR gate, and an AND gate.

15. The communication system of claim 1, wherein the Error Location Polynomial (ELP) module is further configured to:
detect rising edge of the error signal received from the syndrome module, using first set of flip flop modules and first set of logic gates associated with the ELP module; and
set a latch module based on the detected rising edge, to enable the clock associated with the ELP module;
generate an error terminate signal based on the enabled clock;
detect rising edge of the error terminate signal, using second set of flip flop modules and second set of logic gates associated with the ELP module; and
reset the latch module based on the detected rising edge, to disable operation of the ELP module.

16. The communication system of claim 15, wherein the first set of flip flop modules and the second set of flip flop modules associated with the ELP module comprises at least one of D-flip flop modules, and wherein the first set of logic gates and the second set of logic gates associated with the ELP module comprises at least one of a NOT gate, an OR gate, and an AND gate.

17. The communication system of claim 1, wherein the chien search module is configured to:
detect rising edge of the error done received from ELP module, using first set of flip flop modules and first set of logic gates associated with the chien search module; and
set a latch module based on the detected rising edge, to enable the clock associated with the ELP module;
generate a chien search terminate signal based on the enabled clock;
detect rising edge of the chien search terminate signal, using second set of flip flop modules and second set of logic gates associated with the chien search module; and
reset the latch module based on the detected rising edge, to disable operation of the chien search module.

18. The communication system of claim 17, wherein the first set of flip flop modules and the second set of flip flop modules associated with the chien search module comprises at least one of D-flip flop modules, and wherein the first set of logic gates and the second set of logic gates associated with the chien search module comprises at least one of a NOT gate, an OR gate, and an AND gate.

19. A communication method for error-proportional energy-saving in encoding and decoding in Body Area Networks (BAN) using Human Body Communication (HBC) comprising:
receiving, by an encoder module, a message signal from one or more data sources, wherein the message symbol comprises one or more data symbols;
encoding, by the encoder module, the one or more data symbols using one or more encoding algorithms;
calculating, by at least one syndrome module, one or more syndrome values for the received one or more encoded data symbols, wherein the number of one or more syndrome values is proportional to twice maximum error correction capacity value of the one or more encoded data symbols;
generating, by the at least one syndrome module, an error signal when the calculated one or more syndrome values corresponds to a non-zero value;
receiving, by at least one clock gate controller, the error signal from the at least one syndrome module;
activating, by the at least one clock gate controller, an Error Location Polynomial (ELP) module when the one or more syndrome values corresponds to a non-zero value;
generating, by the at least one clock gate controller, an error indication signal, based on the activated ELP module, wherein the error indication signal corresponds to number of errors present in the one or more encoded data symbols;
activating, by the at least one clock gate controller, an Error Magnitude Polynomial (EMP) solver module and a chien search module based on determining polarity of the error indication signal; and
decoding, by the at least one clock gate controller, the one or more encoded data symbols based on the activated EMP solver module and the chien search module.

20. A non-transitory computer-readable medium comprising machine-readable instructions that are executable by a processor to:
receive a message signal from one or more data sources, wherein the message symbol comprises one or more data symbols;
encode the one or more data symbols using one or more encoding algorithms;
calculate one or more syndrome values for the received one or more encoded data symbols, wherein the number of one or more syndrome values is proportional to twice maximum error correction capacity value of the one or more encoded data symbols;
generate an error signal when the calculated one or more syndrome values corresponds to a non-zero value;
receive the error signal from the at least one syndrome module;
activate an Error Location Polynomial (ELP) module when the received error signal exceeds a predefined threshold value;
generate an error indication signal, based on the activated ELP module, wherein the error indication signal corresponds to number of errors present in the one or more encoded data symbols;
activate an Error Magnitude Polynomial (EMP) solver module and a chien search module based on determining a polarity of the error indication signal; and
decode the one or more encoded data symbols based on the activated EMP solver module and the chien search module.
